(19) United States
(12) Patent Application Publication
(10) Pub. No.: US 2026/0206348 A1
(43) Pub. Date: Jul. 16, 2026

(54) SOLID-STATE IMAGE SENSOR

(71) Applicant: SAMSUNG ELECTRONICS CO., LTD., Suwon-si (KR)

(72) Inventors: Junya HIRATA, Yokohama-shi (JP); Kazufumi Shiozawa, Yokohama-shi (JP); Takayuki Ogasahara, Yokohama-shi (JP)

(73) Assignee: SAMSUNG ELECTRONICS CO., LTD., Suwon-si (KR)

(21) Appl. No.: 19/358,692

(22) Filed: Oct. 15, 2025

(30) Foreign Application Priority Data
Jan. 15, 2025 (JP) 2025-005406
Jan. 21, 2025 (JP) 2025-008148
Jan. 23, 2025 (JP) 2025-009777
May 14, 2025 (KR) 10-2025-0062610

(51) Int. Cl. H10F 39/00; H04N 25/704

(52) U.S. Cl. CPC H10F 39/8063; H04N 25/704

(57) ABSTRACT

A phase-difference detection pixel includes an optical path shortening layer provided between a second on-chip lens and a second photoelectric converter. The optical path shortening layer has an incident surface into which the incident light is incident, and has a refractive index higher than an adjacent film. The second on-chip lens, the optical path short axis layer and the second light-transmitting layer have different pupil correction amounts.

### CROSS-REFERENCE TO RELATED APPLICATIONS

This application is based on and claims benefit of priority to Japanese Patent Application Nos. 2025-005406, 2025-008148, 2025-009777 filed on January 15, 2025, January 21, 2025, and January 23, 2025 in the Japanese Intellectual Property Office and Korean Patent Application No. 10-2025-0062610 filed on May 14, 2025 in the Korean Intellectual Property Office, the disclosure of which is incorporated herein by reference in its entirety.

### BACKGROUND

### Field

The disclosure relates to a solid-state image sensor.

### Description of Related Art

Electronic devices having image capturing functions, such as a digital still camera and a smartphone, use solid-state image sensors such as a complementary metal oxide semiconductor (CMOS) image sensor.

In a related art solid-state image sensor, phase-difference detection pixels capable of detecting a phase-difference of an image surface are provided separately from pixels generating electric signals according to incident light on a pixel array (see, for example, Japanese Patent Publication No. 2014-236411). In the related art solid-state image sensor, in order to suppress the deterioration of autofocus (AF) precision, in a plurality of predetermined phase-difference detection pixels among the phase-difference detection pixels, an on-chip lens is provided so as to have a shift amount different from an injection pupil correction amount according to the arrangement of the predetermined phase-difference detection pixels.

### SUMMARY

In a solid-state image sensor having a phase-difference detection pixel, the phase-difference detection pixel has a different pixel size from pixels provided around the phase-difference detection pixel. The pixel size of the phase-difference detection pixel is relatively greater than the pixel sizes of the pixels neighboring the phase-difference detection pixel. Accordingly, in the solid-state image sensor, a pupil correction amount of the phase-difference detection pixel and a pupil correction amount of the pixels provided around the phase-difference detection pixel are different. Furthermore, in the solid-state image sensor, for the pupil correction amount between the phase-difference detection pixel and the pixel, a difference between both pupil correction amounts increases as an image height is higher.

As described above, in the solid-state image sensor, since the pupil correction amounts of the pixels and the phase-difference detection pixel are different, there are cases in which an on-chip lens of the phase-difference detection pixel provided in a position having a high image height overlaps an on-chip lens of an adjacent pixel. As such, the solid-state image sensor has a problem in that color mixing or sensitivity degradation occurs around the phase-difference detection pixel, especially at the boundary of a pixel adjacent to the phase-difference detection pixel, resulting in significantly deteriorating image quality.

The disclosure has been made in consideration of the above-described problems, and specifically, provides a solid-state image sensor capable of reducing a pupil correction amount of a phase-difference detection pixel, thereby reducing a sensitivity difference between pixels adjacent to a phase-difference detection pixel.

According to an aspect of the disclosure, there is provided a solid-state image sensor including: a pixel array in which a plurality of pixels configured to generate an electric signal according to incident light are arranged in a two-dimensional shape, the plurality of pixels including a plurality of first pixels and a plurality of second pixels, a first pixel, among the plurality of first pixels, includes: a first photodiode; a first lens provided on the first photodiode; and a first light-transmitting layer configured to transmit light having a first wavelength in the incident light, a second pixel, among the plurality of second pixels, includes: a second photodiode; a second lens provided on the second photodiode, the second lens having a greater diameter than the first lens; a second light-transmitting layer configured to transmit the light having a second wavelength in the incident light; and an optical path shortening layer provided between the second lens and the second photodiode, wherein the optical path shortening layer has a refractive index higher than a refractive index of an adjacent film, and wherein the second pixel is provided in a region of the pixel array requiring pupil correction, and wherein the second lens, the optical path shortening layer and the second light-transmitting layer of the second pixel have different pupil correction amounts, respectively.

According to an aspect of the disclosure, there is provided a solid-state image sensor including: a pixel array on a chip substrate, the pixel array including a first pixel configured to generate an electric signal according to incident light and a second pixel configured to detect a phase-difference, wherein the first pixel includes: a first photodiode; a first lens provided on the first photodiode; a first light-transmitting layer provided between the first lens and the first photodiode, the first light-transmitting layer configured to transmit a first wavelength; and a first separation wall provided between the first light-transmitting layer and a first adjacent first light-transmitting layer adjacent to the first light-transmitting layer, and wherein the second pixel includes: a second photodiode; a second lens provided on second photodiode, the second lens having a diameter greater than a diameter of the first lens; a second light-transmitting layer provided between the second lens and the second photodiode, the second light-transmitting layer configured to transmit a second wavelength; and a second separation wall provided between the second light-transmitting layer and a second adjacent first light-transmitting layer adjacent to the second light-transmitting layer, and wherein in an outer peripheral portion of the pixel array, a pupil correction amount of the second light-transmitting layer in the second pixel is greater than a pupil correction amount of the second separation wall of the second pixel.

According to an aspect of the disclosure, there is provided a solid-state image sensor including: a pixel array on a chip substrate, the pixel array including a first pixel configured to generate an electric signal according to incident light and a second pixel configured to detect a phase-difference, wherein the first pixel includes: a first photodiode; a first lens provided on the first photodiode; and a first light-transmitting layer provided between the first lens and the first photodiode, the first light-transmitting layer configured to transmit a first wavelength, wherein the second pixel includes: a second photodiode; a pixel separation wall formed between the second photodiode and the first photodiode adjacent to the second photodiode; a boundary separation wall separating the second photodiode into a plurality of portions; a second lens provided on the second photodiode, the second lens having a diameter greater than a diameter of the first lens; and a second light-transmitting layer provided between the second lens and the second photodiode, the second light-transmitting layer configured to transmit a second wavelength, and wherein a center of the second photodiode in the second pixel located in an outer peripheral portion of the pixel array is provided on an outer peripheral side of the pixel array as compared to a center of the pixel separation wall.

According to one or more embodiments of the disclosure, the pupil correction amount of the phase-difference detection pixel may decrease to reduce a sensitivity difference between the pixels.

According to one or more embodiments the disclosure, since the pupil correction amount of the second light-transmitting layer in the phase-difference detection pixel of an outer peripheral portion of the pixel array is greater than the pupil correction amount of the second separation wall of the phase-difference detection pixel, it may be possible to reduce a difference between the pupil correction amount of the phase-difference detection pixel and the pupil correction amount of pixels provided around the phase-difference detection pixel, and to reduce a sensitivity difference between pixels adjacent to the phase-difference detection pixel.

According to one or more embodiments the disclosure, since the center of the boundary separation wall in the phase-difference detection pixel in the outer peripheral portion of the pixel array is provided on an outer peripheral side of a pixel array as compared to a center of a pixel separation wall, even in an example case in which the pupil correction amount of the phase-difference detection pixel is made the same as the pupil correction amount of the pixels provided around the phase-difference detection pixel, it may be possible to focus light on the center of a plurality of second photoelectric converters 23, and since an on-chip lens of the phase-difference detection pixel and an on-chip lens of the pixel adjacent to the phase-difference detection pixel may be configured not to overlap each other, it may be possible to reduce a sensitivity difference between the pixels adjacent to the phase-difference detection pixel.

### BRIEF DESCRIPTION OF DRAWINGS

The above and other aspects, features, and advantages of the disclosure will be more clearly understood from the following detailed description, taken in conjunction with the accompanying drawings, in which:

FIGS. 1A and 1B are block diagrams illustrating a solid-state image sensor according to an example embodiment of the disclosure;

FIG. 2A is a partially enlarged plan view of a solid-state image sensor according to an example embodiment of FIG. 1A;

FIG. 2B is a partially cut cross-sectional schematic diagram of a solid-state image sensor according to an example embodiment of the disclosure;

FIG. 3A is a schematic diagram illustrating a pixel size of a phase-difference detection pixel;

FIG. 3B is a schematic diagram illustrating a pixel size of a phase-difference detection pixel;

FIG. 3C is a schematic diagram illustrating a pixel size of a phase-difference detection pixel;

FIG. 4A is a schematic diagram illustrating an example of a configuration of a first on-chip lens and a second on-chip lens, FIG. 4B is a schematic diagram illustrating an example of a configuration of a light-transmitting layer separation wall, and FIG. 4C is a schematic diagram illustrating an example of a configuration of a pixel separation wall and a boundary separation wall;

FIG. 4D is a schematic diagram illustrating an example of another configuration of the first on-chip lens and the second on-chip lens, FIG. 4E is a schematic diagram illustrating an example of another configuration of the light-transmitting layer separation wall, and FIG. 4F is a schematic diagram illustrating an example of another configuration of the pixel separation wall and the boundary separation wall;

FIG. 5 is a view illustrating an example of an arrangement of a phase-difference detection pixel provided in a pixel array;

FIGS. 6A and 6B are views illustrating an example of an arrangement of each portion of a phase-difference detection pixel provided in a center of a pixel array;

FIGS. 6C and 6D are views illustrating an example of an arrangement of each portion of a phase-difference detection pixel provided in a peripheral portion of the pixel array;

FIGS. 7A, 7B, 7C, 7D, 7E, and 7F are views illustrating an example of a shape of an optical path shortening layer as viewed from the plane;

FIGS. 8A, 8B, and 8C are views illustrating an example of a cross-sectional shape of the optical path shortening layer;

FIG. 9A is a cross-sectional schematic diagram illustrating an optical path of incident light to a phase-difference detection pixel of a solid-state image sensor according to an example embodiment;

FIG. 9B is a cross-sectional schematic diagram illustrating an optical path of incident light to a phase-difference detection pixel of a related art solid-state imaging sensor without an optical path shortening layer;

FIG. 10 is a cross-sectional schematic diagram of a solid-state imaging sensor of modified example 1;

FIG. 11A is a cross-sectional schematic diagram illustrating a shape of an anti-reflection portion in a solid-state imaging sensor of modified example 2;

FIG. 11B is a cross-sectional schematic diagram illustrating another shape of an anti-reflection portion in a solid-state imaging sensor of modified example 2;

FIG. 12 is a cross-sectional schematic diagram of a solid-state imaging sensor of modified example 3;

FIG. 13 is a graph illustrating a simulation result of an example embodiment;

FIG. 14 is an image diagram illustrating that a pupil correction amount of a second light-transmitting layer of a phase-difference detection pixel in a pixel array differs depending on a position;

FIG. 15 is a plan view illustrating a portion of a solid-state imaging sensor according to the example embodiment of FIG. 1B;

FIG. 16A is a cross-sectional view taken along line A-A of FIG. 15;

FIG. 16B is a cross-sectional view, taken along line A-A of FIG. 15, illustrating a magnitude relation between pupil correction amounts;

FIG. 17 is a view corresponding to FIG. 16A of a solid-state image sensor according to a comparative example;

FIG. 18 is a graph illustrating a sensitivity difference between the same colors of the solid-state image sensors according to an example embodiment and a comparative example;

FIG. 19 is a graph illustrating a separation ratio of the solid-state image sensors according to an example embodiment and a comparative example;

FIG. 20 is a view corresponding to FIG. 16A of a solid-state image sensor according to modified example 1 of the solid-state image sensor;

FIG. 21 is a view corresponding to FIG. 16A of a solid-state image sensor according to modified example 2 of the solid-state image sensor;

FIG. 22 is a view corresponding to FIG. 16A of a solid-state image sensor according to modified example 3 of the solid-state image sensor;

FIG. 23 is an exploded view illustrating a modified example 1 of a phase-difference detection pixel;

FIG. 24 is an exploded view illustrating a modified example 2 of a phase-difference detection pixel;

FIG. 25 is a plan view illustrating a modified example of a pixel separation wall;

FIG. 26 is an image view illustrating that in a center of a boundary separation wall of a phase-difference detection pixel in a pixel array, an amount of deviation from a center of the pixel separation wall varies depending on the position;

FIG. 27 is a cross-sectional view taken along the line A-A of FIG. 15;

FIG. 28 is a view corresponding to FIG. 27 of the solid-state image sensor according to modified example 1;

FIG. 29 is a view corresponding to FIG. 27 of the solid-state image sensor according to modified example 2;

FIG. 30 is a view corresponding to FIG. 27 of the solid-state image sensor according to modified example 3; and

FIG. 31 is a plan view illustrating the arrangement position of a metal light-shielding wall of the solid-state image sensor according to modified example 3.

### DETAILED DESCRIPTION

Hereinafter, example embodiments of the disclosure will be described with reference to the accompanying drawings.

Hereinafter, with reference to the accompanying drawings, example embodiments of the disclosure will be described in detail. In the drawings below, the same reference numerals refer to the same components, and the sizes of each component in the drawings may be exaggerated for clarity and convenience of explanation. In addition, the example embodiments described below are merely exemplary, and various modifications are possible from such example embodiments.

Hereinafter, the expressions “above” or “on” may include not only those directly above in contact, but also those directly above in non-contact. Similarly, the terms “below” may include not only those directly below in contact, but also those directly below in non-contact.

Singular expressions include plural expressions, unless the context clearly indicates that they are singular. In addition, when a portion is said to “comprise,” “include,” or “have” a component, this does not exclude other components, but means that other components may be additionally included, unless there is a specific description to the contrary.

For the operations of a method, if the order is explicitly described or there is no description to the contrary, the operations are performed in the appropriate order. It is not necessarily limited to the order of the description of the operations. The use of all examples or exemplary terms is only for the purpose of explaining technical concepts, and the scope is not limited by the examples or exemplary terms, unless limited by the scope of the claims.

Meanwhile, in the following description, when ordinal numbers such as “first” and “second” are attached to the description, they are used for convenience and do not specify any order, unless specifically stated otherwise.

The configuration of a solid-state image sensor 1 according to an example embodiment of the disclosure will be described.

Here, for convenience of explanation, an XYZ orthogonal coordinate system is set for the solid-state image sensor 1. A direction parallel to an X-axis within a given plane is referred to as an X-axis direction. A direction parallel to a Y-axis orthogonal to the X-axis within a given plane is referred to as a Y-axis direction. A direction parallel to a Z-axis orthogonal to each of the X-axis and Y-axis is referred to as a Z-axis direction. In an example embodiment, the given plane is parallel to a horizontal plane in an X-Y plane, and the Z-axis is a vertical direction, orthogonal to the given plane. Accordingly, the Z-axis direction corresponds to a stacking direction (or a thickness direction) of each component included in the solid-state image sensor 1, and the X-axis direction and the Y-axis direction correspond to a plane direction, orthogonal to the stacking direction.

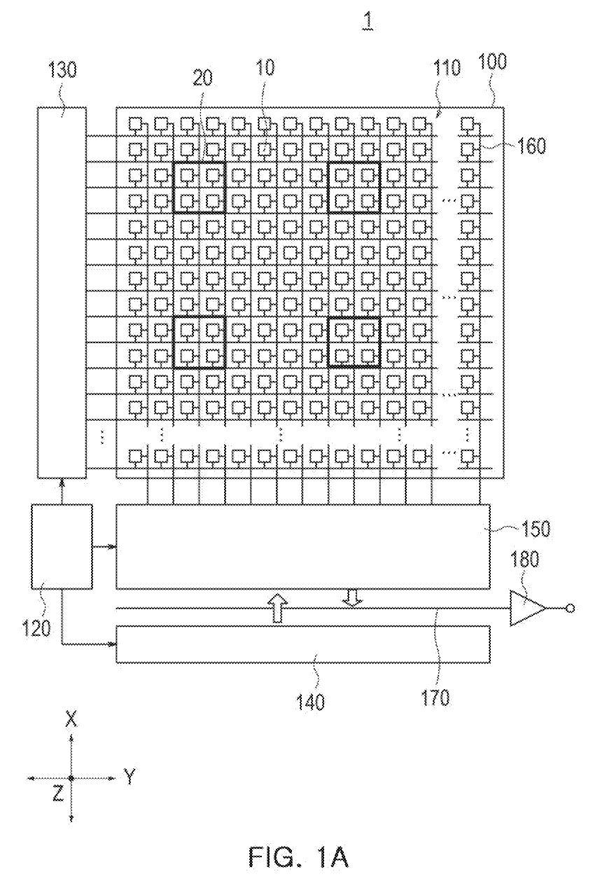

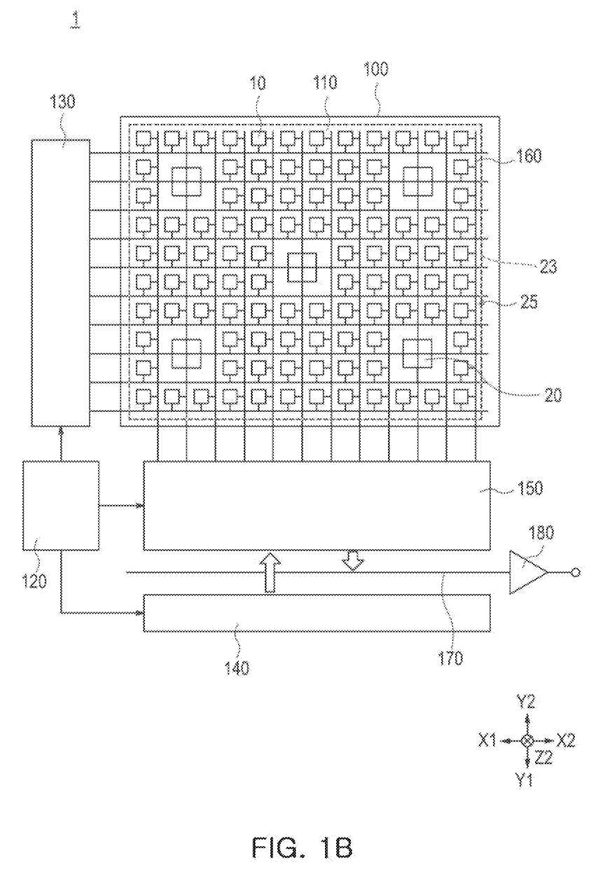

Referring to FIGS. 1A and 1B, the solid-state image sensor 1 may include a pixel 10, a phase-difference detection pixel 20, and a chip substrate 100.

The solid-state image sensor 1 may be (or may form) a complementary metal oxide semiconductor (CMOS) image sensor.

As illustrated in FIGS. 1A and 1B, the solid-state image sensor 1 may include a pixel array 110 having a plurality of pixels 10 configured to output a pixel signal on a chip substrate 100 and a plurality of phase-difference detection pixels 20 configured to detect an image surface phase difference. The solid-state image sensor 1 may further include a control circuit 120 configured to generate an operating signal for operating each part, a vertical drive circuit 130 configured to scan each pixel 10 in a vertical direction (Y-axis direction in the drawing), a second direction orthogonal to the first direction, and configured to control an output of a pixel signal according to the amount of light received by each pixel 10, a horizontal drive circuit 140 configured to output a scanning pulse in a horizontal direction (e.g., X-axis direction in the drawing), the first direction, a column signal processing circuit 150 configured to process a pixel signal output from each pixel 10 and generate an image signal, a vertical signal line 160 configured to transmit a pixel signal generated by each pixel 10 to the column signal processing circuit 150, a horizontal signal line 170 configured to output an image signal from the column signal processing circuit 150, and an output circuit 180 configured to process an image signal received by interposing the horizontal signal line 170 and outputting a signal after the processing. In the solid-state image sensor 1 illustrated in FIG. 1A, an area surrounded by a thick line in the pixel array 110 represents a phase-difference detection pixel 20. In FIG. 1A, the phase-difference detection pixels 20 are formed of four pixels surrounded by regular pixels 10 and having a same size as the regular pixel 10, while, in FIG. 1B, the phase-difference detection pixel 20 is formed of a single pixel surrounded by regular pixels 10 and having a size greater than the regular pixel 10.

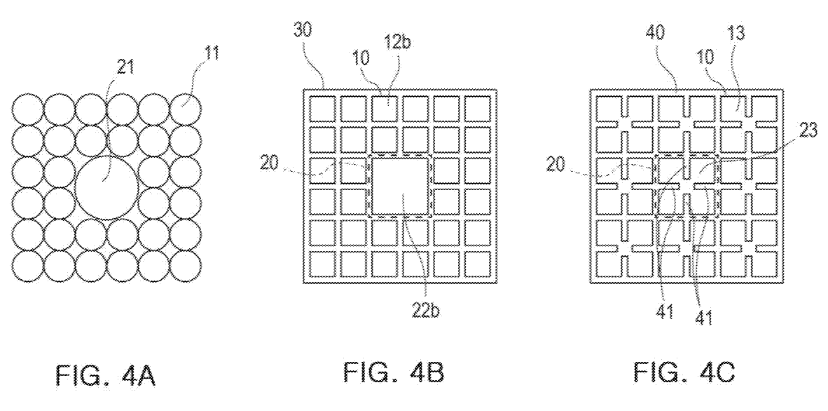

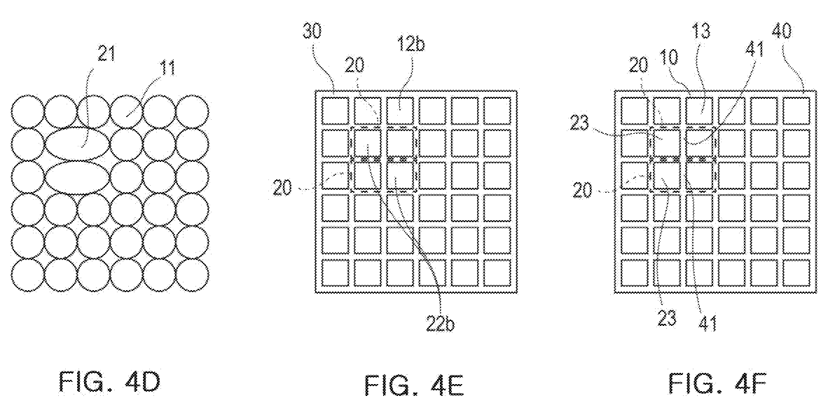

The chip substrate 100 may be formed of silicon or the like, and the pixel 10 and the phase-difference detection pixel 20 may be formed on a substrate. The chip substrate 100 may form a first photoelectric converter 13 and a second photoelectric converter 23 (see FIG. 4C). For example, the first photoelectric converter 13 and the second photoelectric converter 23 may be formed in the chip substrate 100. In this specification, the ‘photoelectric converter’ may also be referred to as a ‘photodiode.’ The chip substrate 100 may have a pixel transistor or an interconnection layer formed on a surface opposite to a surface of incident light (hereinafter, also referred to as “incident light L”) incident on the solid-state image sensor 1. The chip substrate 100 may output a pixel signal, which is an electric signal converted from incident light L received by the first photoelectric converter 13 and the second photoelectric converter 23, to the control circuit 120.

In the solid-state image sensor 1, for components other than the pixels 10 and phase-difference detection pixels 20 formed in the pixel array 110, a known configuration in the technical field of solid-state image sensors may be arbitrarily or selectively adopted. For this reason, in this specification, some descriptions of components other than the pixels 10 and the phase-difference detection pixels 20 are omitted.

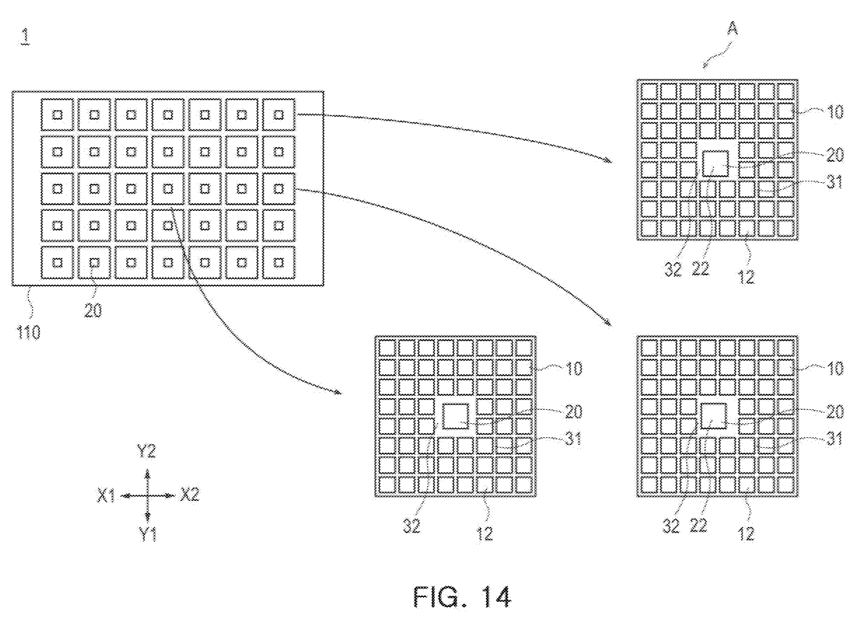

In the solid-state image sensor 1 according to FIG. 1B, as illustrated in FIGS. 14, 15, 16A, and 16B, the pupil correction amount of a second light-transmitting layer 22 in the phase-difference detection pixel 20 of an outer peripheral portion (see symbol A of FIG. 14) of the pixel array 110 is configured to be greater than the pupil correction amount of a second separation wall 32 of the phase-difference detection pixel 20. The detailed configuration will be described below.

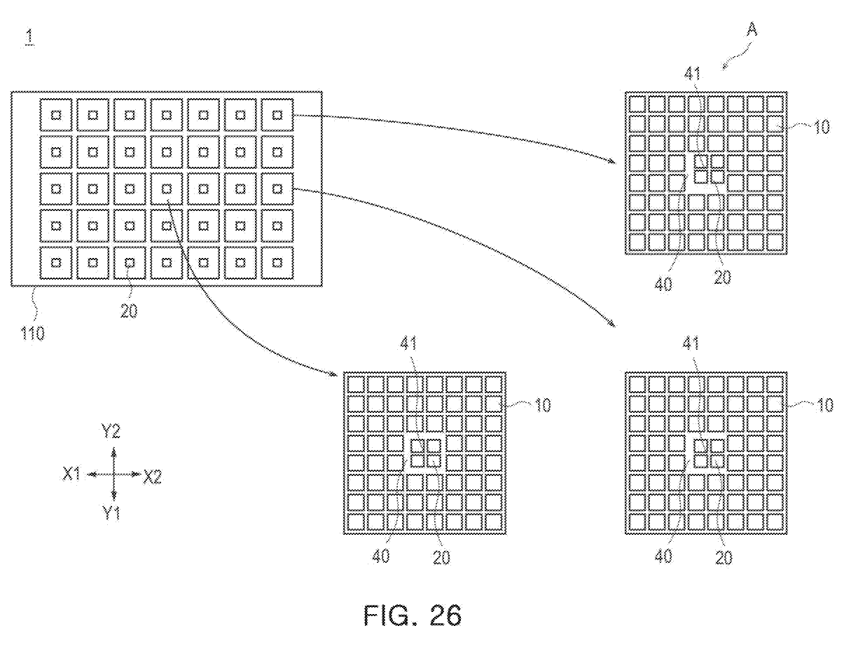

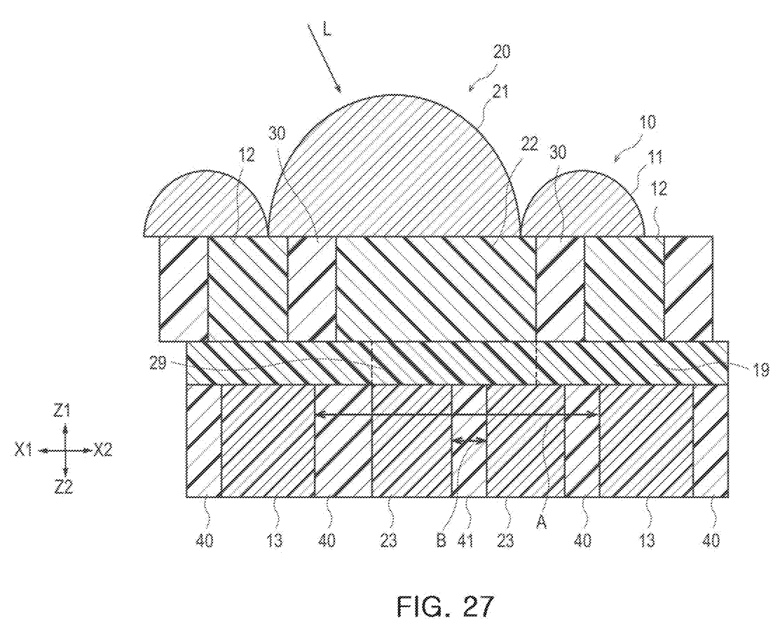

In the solid-state image sensor 1 according to FIG. 1B, as illustrated in FIGS. 26 and 27, a center of the second photoelectric converter separated into a plurality of parts by a boundary separation wall 41 in the phase-difference detection pixel 20 of an outer peripheral portion (see symbol A of FIG. 26) of the pixel array 110 is provided on an outer peripheral side of the pixel array 110 as compared to a center of a pixel separation wall, 40 toward the outer peripheral side of the pixel array 110. The detailed configuration will be described below.

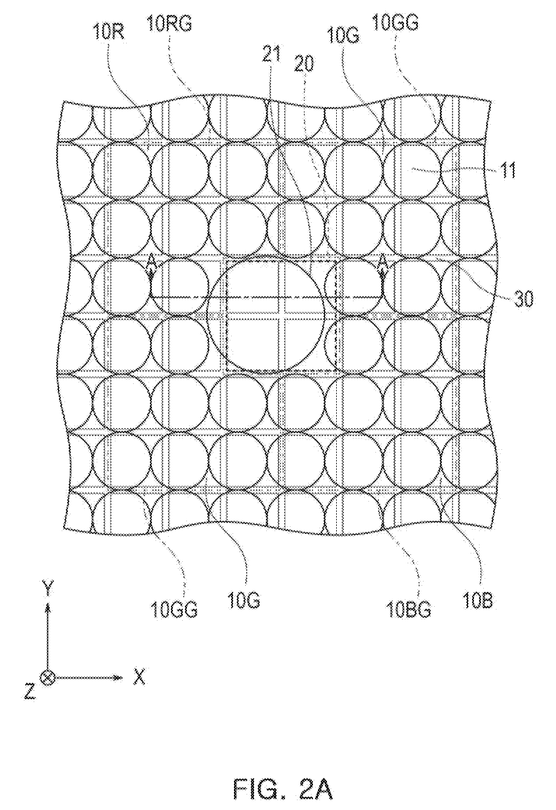

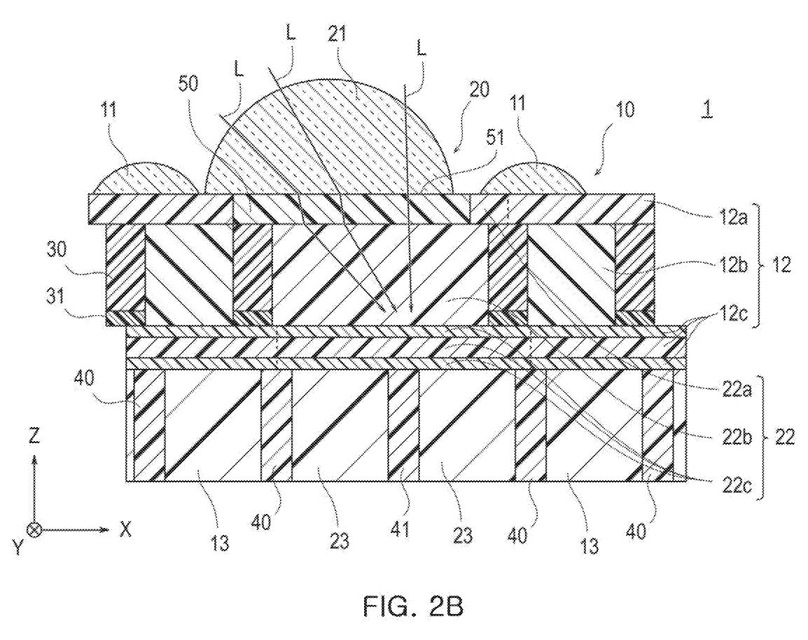

FIG. 2A illustrates an enlarged plan view of a portion of the solid-state image sensor 1 of an example embodiment cut in a horizontal direction (cut on the X-Y plane). FIG. 2B illustrates a schematic cross-sectional view (cross-section A-A of FIG. 2A) in which the solid-state image sensor 1 is partially cut.

FIG. 2A illustrates a portion of one side of the pixel array 110, for example, a portion of an outer peripheral portion toward the right, as compared to the center of the pixel array 110, and a center of a second on-chip lens 21 may be provided in a form spaced apart from the center of the pixel 10. The pixel 10, as illustrated in FIG. 2A, may include a red pixel 10R, a green pixel 10G and a blue pixel 10B. The pixels 10 may be arranged two-dimensionally (for example, in a matrix shape) on the chip substrate 100. An arrangement of the pixels 10 may be appropriately set according to the specifications of the solid-state image sensor 1. The solid-state image sensor 1 illustrated in FIG. 2A may have a red pixel group 10RG, a green pixel group 10GG, and a blue pixel group 10BG provided around the phase-difference detection pixel 20 having a pixel size of 2 pixels × 2 pixels surrounded by a dotted line. That is, in FIG. 2A, each pixel group is configured as a Bayer array in a group unit. The red pixel group 10RG may include eight red pixels 10R. The green pixel group 10GG may include eight green pixels 10G. The blue pixel group 10BG may include eight blue pixels 10B.

The pixel 10 may include, as illustrated in FIG. 2B, in order from the incident side of the incident light L, a first on-chip lens 11, a first multilayer film layer 12, and a first photoelectric converter 13. The pixel 10 may be independently separated from each of the adjacent pixels 10 or the phase-difference detection pixels 20 by a light-transmitting layer separation wall 30 or a pixel separation wall 40. A dotted line illustrated in FIG. 2B indicates a boundary position between the first multilayer film layer 12 and a second multilayer film layer 22 described below.

The first on-chip lens 11 may be formed on a first planarizing layer 12a of the first multilayer film layer 12. The first on-chip lens 11 may be arranged to correspond to each pixel 10. For example, the first on-chip lens 11 may be arranged two-dimensionally (for example, in a matrix form) on a plane. The first on-chip lens 11 may have a convex shape and a predetermined radius of curvature so that incident light L is focused on the first photoelectric converter 13. The first on-chip lens 11 may be formed using an organic material such as a styrene-based resin, an acrylic-based resin, a styrene-acrylic copolymer-based resin, or a siloxane-based resin, for example. The first on-chip lens 11 may be provided so as to deviate in a predetermined direction by a pupil correction amount according to an arrangement position of the pixels 10 in the pixel array 110, as illustrated in FIG. 2A.

The first multilayer film layer 12 may include a first planarizing layer 12a, a first light-transmitting layer 12b, and a first anti-reflection layer 12c. The first multilayer film layer 12 may have a layer configuration including at least the first light-transmitting layer 12b and the first anti-reflection layer 12c, and may further include another layer other than the layers described above.

The first planarizing layer 12a may be formed between the first on-chip lens 11 and the first light-transmitting layer 12b. The first planarizing layer 12a may have high transmittance for light incident on the first photoelectric converter 13 and may provide a flat formation surface for the first on-chip lens 11. The first planarizing layer 12a may be formed of, for example, an organic material such as a resin.

The first light-transmitting layer 12b may be formed between the first planarizing layer 12a and the first photoelectric converter 13, and may be arranged two-dimensionally (for example, in a matrix shape) to correspond to each unit pixel. The first light-transmitting layer 12b may have a function of transmitting light having a specific wavelength in a visible light range. For the reason, the first light-transmitting layer 12b may function as a variety of color filters for each unit pixel.

The first light-transmitting layer 12b may function as a red color filter configured to transmit red light as light having a specific wavelength and to absorb green light and blue light to correspond to a red pixel 10R. The first light-transmitting layer 12b may function as a green color filter configured to transmit green light as light having a specific wavelength and to absorb red light and blue light to correspond to a green pixel 10G. The first light-transmitting layer 12b may function as a blue color filter configured to transmit blue light as light having a specific wavelength to correspond to the blue pixel 10B, and to absorb red light and green light. In addition, the first light-transmitting layer 12b may function as a white filter configured to transmit light of approximately an entire visible light region as light having a specific wavelength.

The first light-transmitting layer 12b may be arranged in a Bayer pattern including the first light-transmitting layer 12b corresponding to the red pixel 10R, the green pixel 10G and the blue pixel 10B. However, this is exemplary, and the first light-transmitting layer 12b may also include a yellow filter, a magenta filter, and a cyan filter. The first light-transmitting layer 12b may be formed by including a pigment or dye of a desired color in a resin having low light absorption.

A light-transmitting layer separation wall 30 having light-shielding properties may be formed at a boundary between the first light-transmitting layer 12b and another adjacent first light-transmitting layer 12b or a second light-transmitting layer 22b of the phase-difference detection pixel 20. Accordingly, the first light-transmitting layers 12b may be separated for each pixel, between the adjacent pixels 10 or between the pixels 10 and the phase-difference detection pixels 20.

The first anti-reflection layer 12c may be formed between the first light-transmitting layer 12b and the first photoelectric converter 13. The first anti-reflection layer 12c may be formed by combining and stacking a layer of a high-refractive material (e.g., silicon nitride (SiN), hafnium oxide (HfO), tantalum oxide (TaO), titanium oxide (TiO), and the like) and a layer of a low-refractive material (e.g., silicon oxide (SiO₂)). According to an embodiment, a number of layers of the high-refractive material and the low-refractive material is not limited to the illustrated in FIG. 2B.

The first photoelectric converter 13 may convert transmitted light of a photoelectric conversion target that has progressed to the first photoelectric converter 13, among the incident light L incident on the solid-state image sensor 1, into an electric signal. The first photoelectric converter 13 may be separated by the pixel separation wall 40 to be separated for each pixel, between the adjacent pixels 10 or between the pixels 10 and the phase-difference detection pixels 20. The first photoelectric converter 13 may include, for example, at least one of a photo diode, a photo transistor, a photo gate, a pinned photo diode, an organic photo diode, a quantum dot, and combinations thereof, but the disclosure is not limited thereto.

In the phase-difference detection pixel 20 illustrated in FIG. 2B, the second on-chip lens 21, the second multilayer film layer 22 and the second photoelectric converter 23 may be provided in order from the incident side of the incident light L. The phase-difference detection pixel 20 may be independently separated from each of the adjacent pixels 10 by the light-transmitting layer separation wall 30 or the pixel separation wall 40.

The phase-difference detection pixel 20 may have a structure in which the second photoelectric converter 23 is separated into a plurality of parts by the boundary separation wall 41. The phase-difference detection pixel 20 may implement autofocus by calculating the amount of focus shift from a phase difference of an image surface acquired from a plurality of pixels 10. For these reasons, an image sensor equipped with the solid-state image sensor 1 may focus on a subject based on a phase difference of the light incident on the pixel 10 without requiring a mechanism dedicated to autofocus.

The second on-chip lens 21 may be formed on a second planarizing layer 22a of the second multilayer film layer 22. The second on-chip lens 21 may be arranged to correspond to each phase-difference detection pixel 20. The second on-chip lens 21 may have a greater diameter than a diameter of the first on-chip lens 11. The second on-chip lens 21 may be formed according to the shape or size of the phase-difference detection pixel 20. The second on-chip lens 21 may have different sizes, such as diameter and height, when viewed from a plane, but may have the same forming materials as the first on-chip lens 11. As illustrated in FIG. 2A, the second on-chip lens 21 may be provided to be shifted in a predetermined direction by a pupil correction amount according to an arrangement position of the phase-difference detection pixel 20 in the pixel array 110.

The second multilayer film layer 22 may include a second planarizing layer 22a, a second light-transmitting layer 22b, and a second anti-reflection layer 22c. The second multilayer film layer 22 may have a layer configuration including at least the second light-transmitting layer 22b and the second anti-reflection layer 22c, and may further include other layers in addition to the layers described above.

The second planarizing layer 22a may be formed between the second on-chip lens 21 and the second light-transmitting layer 22b. The second planarizing layer 22a may have the same configuration as the first planarizing layer 12a.

The second light-transmitting layer 22b may be formed between the second planarizing layer 22a and the second photoelectric converter 23. The second light-transmitting layer 22b may transmit light having a specific wavelength photoelectrically converted in the second photoelectric converter 23. The second photoelectric converter 23 may have the same composition as the first photoelectric converter 13 in terms of forming materials, and the like.

According to an embodiment, a light-transmitting layer separation wall 30 may be provided between the second light-transmitting layer 22b and the first light-transmitting layer 12b of the adjacent pixel 10. For example, the light-transmitting layer separation wall 30 may have light-shielding properties and may be formed at a boundary between the second light-transmitting layer 22b and the first light-transmitting layer 12b of the adjacent pixel 10. Accordingly, the second light-transmitting layers 22b of each pixel may be separated between the adjacent pixel 10.

The second anti-reflection layer 22c may be formed between the second light-transmitting layer 22b and the second photoelectric converter 23. The second anti-reflection layer 22c may have the same composition as the first anti-reflection layer 12c in terms of the forming material, and the like.

The second photoelectric converter 23 converts the transmitted light of the photoelectric conversion target that has progressed to the second photoelectric converter 23, among the incident light L incident on the phase-difference detection pixel 20, into an electric signal. The second photoelectric converter 23 is surrounded by the pixel separation wall 40 so as to be separated from the adjacent pixels 10. The second photoelectric converter 23 may be configured in the same manner as the first photoelectric converter 13 in terms of the forming material, and the like.

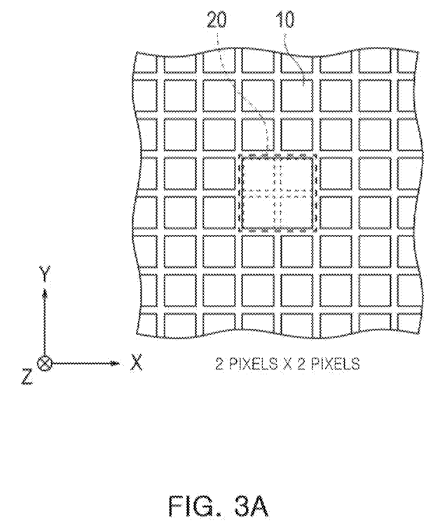

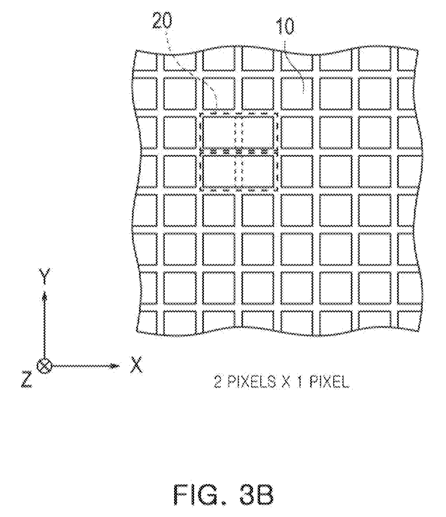

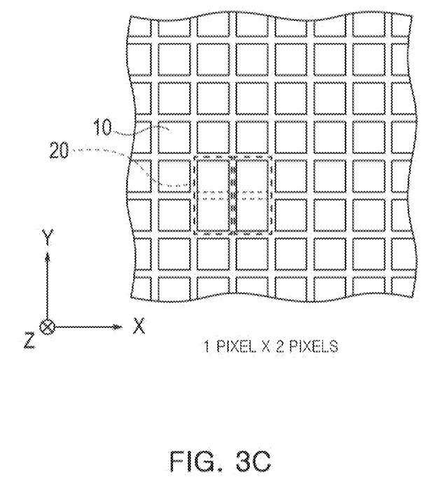

According to an embodiment, the phase-difference detection pixel 20 illustrated in FIG. 3A may include four second photoelectric converters 23 arranged in a 2 × 2 array. The four second photoelectric converters 23 arranged in the 2 × 2 array may have a structure in which each of the four second photoelectric converters 23 is separated by the boundary separation wall 41 provided in the X-direction and the Y-direction.

According to an embodiment, the phase-difference detection pixel 20 illustrated in FIG. 3B may have a greater element size than that of the pixel 10. For example, the pixel size of the phase-difference detection pixel 20 may have a length of one pixel of the pixel 10 in the horizontal direction (X-axis direction) which is the first direction, as illustrated in FIG. 3B, and may have a length of two pixels of the pixel 10 in the vertical direction (Y-axis direction) which is the second direction. In this case, the pixel of the phase-difference detection pixel 20 may have two second photoelectric converters 23, and the two second photoelectric converters 23 may have a structure in which the two second photoelectric converters 23 are each separated by the boundary separation wall 41 provided in the X-axis direction.

According to an embodiment, the phase-difference detection pixel 20 illustrated in FIG. 3C may have a greater element size than that of the pixel 10. The pixel size of the phase-difference detection pixel 20 may have a length of two pixels of the pixel 10 in the horizontal direction (X-axis direction) which is the first direction, as illustrated in FIG. 3C, and may have a length of one pixel of the pixel 10 in the vertical direction (Y-axis direction) which is the second direction. In this case, the pixel of the phase-difference detection pixel 20 may have two second photoelectric converters 23, and the two second photoelectric converters 23 may have a structure in which the two second photoelectric converters 23 are each separated by a boundary separation wall 41 arranged in the Y-axis direction.

However, the pixel size of the phase-difference detection pixel 20 is not limited to the size illustrated in FIGS. 3A, 3B, and 3C, and may be formed to have a greater element size or to have the same pixel size as the pixel 10.

FIGS. 4A, 4B, 4C, 4D, 4E, and 4F are schematic diagrams illustrating other examples of the shapes of the on-chip lens, the light-transmitting layer separation wall and the pixel separation wall, which form each pixel of the solid-state image sensor 1. FIG. 4A illustrates an example of the configuration of the first on-chip lens 11 and the second on-chip lens 21 of the solid-state image sensor 1, FIG. 4B illustrates an example of the configuration of the light-transmitting layer separation wall 30, and FIG. 4C illustrates an example of the configuration of the pixel separation wall 40 and the boundary separation wall 41. FIG. 4D illustrates an example of another configuration of the first on-chip lens 11 and the second on-chip lens 21 of the solid-state image sensor 1, FIG. 4E illustrates an example of another configuration of the light-transmitting layer separation wall 30, and FIG. 4F illustrates an example of another configuration of the pixel separation wall 40 and the boundary separation wall 41. The phase-difference detection pixel 20 and pixel 10 of FIG. 3A may have the configuration of FIGS. 4A, 4B, and 4C.

The light-transmitting layer separation wall 30 may be formed to surround the first light-transmitting layer 12b in the pixel 10 or the second light-transmitting layer 22b of the phase-difference detection pixel 20. The light-transmitting layer separation wall 30 may be provided in a grid shape when viewed from the plane, as illustrated in FIG. 4B and 4E, and may form a boundary between adjacent first light-transmitting layers 12b or adjacent second light-transmitting layers 22b to partition and separate each layer into a predetermined size. The light-transmitting layer separation wall 30 may have at least a function of preventing vignetting of incident light L incident on the pixel 10 and a function of blocking incoming light from an adjacent pixel 10. Accordingly, the light-transmitting layer separation wall 30 may be formed to have a height and width that satisfy these functions. The light-transmitting layer separation wall 30 may include a dielectric having low light absorption, such as silicon oxide (SiO₂) or silicon nitride (SiN).

Referring to FIG. 2B, a light-shielding portion 31 may be formed between the light-transmitting layer separation wall 30 and the first anti-reflection layer 12c, and between the light-transmitting layer separation wall 30 and the second anti-reflection layer 22c. The light-shielding portion 31 may be formed to surround the first light-transmitting layer 12b or the second light-transmitting layer 22b. The light-shielding portion 31 may be provided between adjacent pixels 10 or phase-difference detection pixels 20, thereby suppressing crosstalk between adjacent pixels, as well as further improving the precision during phase difference detection. The light-shielding portion 31 may include a metal material including, but not limited to, titanium nitride (TiN), titanium (Ti), tungsten (W), aluminum (Al), molybdenum (Mo), and nickel (Ni).

According to an embodiment, the pixel separation wall 40 may be formed with a Deep Trench Isolation (DTI). The pixel separation wall 40 may be formed to surround the first photoelectric converter 13 of the pixel 10 or the second photoelectric converter 23 of the phase-difference detection pixel 20, as illustrated in FIGS. 2A and 2B. Accordingly, the first photoelectric converter 13 of the pixel 10 and the second photoelectric converter 23 of the phase-difference detection pixel 20 may be separated, respectively. The pixel separation wall 40 may include a boundary separation wall 41 that divides the second photoelectric converter 23 of the phase-difference detection pixel 20 into a plurality of parts. The boundary separation wall 41 may divide the second photoelectric converter 23 into a predetermined number so that the second photoelectric converter 23 may detect a phase difference of a upper surface within the phase-difference detection pixel 20.

According to an embodiment as illustrated in FIG. 4C, the pixel separation wall 40 may be formed so as not to surround a portion of an entire perimeter of the first photoelectric converter 13 or the second photoelectric converter 23. For example, the pixel separation wall 40 may be configured using the boundary separation wall 41 without a separation wall in the center of four pixels (e.g., four pixels 10, or four pixels included in the phase-difference detection pixel 20). Accordingly, even if this configuration may affect the spectral characteristics, the noise reduction effect may be improved.

The pixel separation wall 40 may be formed by separating the first photoelectric converter 13 or the second photoelectric converter 23 by a unit pixel size, as illustrated in FIG. 4F. In the case of FIGS. 4D, 4E, and 4F, the pixel separation wall 40 may be independently divided according to the division number of the second photoelectric converter 23 of the phase-difference detection pixel 20. The phase-difference detection pixel 20 and the pixel 10 of FIG. 3A can have the configurations of FIGS. 4E and 4F.

However, the shape of the pixel separation wall 40 is not limited to the shape illustrated in FIGS. 4A, 4B, 4C, 4D, 4E, and 4F, and may be a shape according to the specifications of the solid-state image sensor 1.

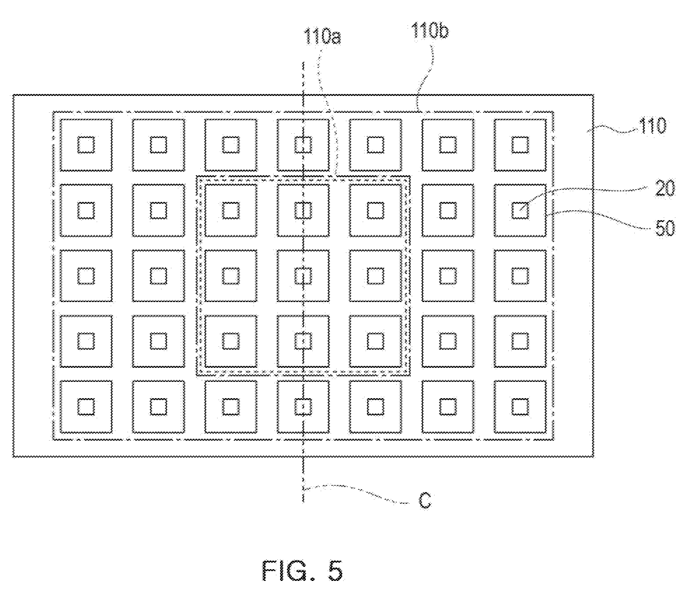

According to the solid-state image sensor 1 of an example embodiment, as illustrated in FIG. 5, a phase-difference detection pixel 20 may be spaced apart from a center 110a of the pixel array 110 at a predetermined interval. For example, the phase-difference detection pixel 20 may be provided at a peripheral portion 110b on an outer peripheral side of the pixel array 110. In the pixel array 110 illustrated in FIG. 5 the illustration of pixels 10 within the unit is omitted, but actually, a plurality of pixels are provided around the phase-difference detection pixels 20. As illustrated in FIG. 5, the center 110a of the pixel array 110 includes a certain range (e.g., a region surrounded by a dotted line) from the center of the pixel array 110 toward the outer peripheral side. As illustrated in FIG. 5, the peripheral portion 110b of the pixel array 110 includes a certain range (e.g., a region surrounded by a dashed line) from an outermost periphery of the pixel array 110 toward the center. The center of the pixel array 110 means a center line C (e.g., a dashed line in the drawing) based on which the pixel array 110 illustrated in FIG. 5 is symmetrical left and right.

The solid-state image sensor 1 may have an optical path shortening layer 50 between the second on-chip lens 21 of the phase-difference detection pixel 20 and the second photoelectric converter 23 to refract an optical path of the incident light L more than surrounding pixels 10 and shorten the optical path.

The optical path shortening layer 50 may be provided between the second on-chip lens 21 and the second light-transmitting layer 22b. The optical path shortening layer 50 may be provided inside the second planarizing layer 22a (or the first planarizing layer 12a) between the second on-chip lens 21 and the second light-transmitting layer 22b, as illustrated in FIG. 2B. Alternatively, the optical path shortening layer 50 may be provided instead of the second planarizing layer 22a. In this case, the optical path shortening layer 50 may also function as the second planarizing layer 22a. The optical path shortening layer 50 may include a high refractive index material, such as SiN, HFO, TaO, or TiO₂, which is higher than a refractive index of other adjacent films (e.g., each layer of the first multilayer film layer 12 or the second multilayer film layer 22).

In the optical path shortening layer 50, a center P1 when viewed from the plane of an incident surface 51 may be provided on a straight line S connecting a center P2 when viewed from the plane of the second on-chip lens 21 and a center P3 (corresponding to a center when viewed from the plane of the second photoelectric converter 23) when viewed from the plane of the phase-difference detection pixel 20. The optical path shortening layer 50 may have a separate pupil correction amount depending on the corresponding phase-difference detection pixel 20. The second on-chip lens 21, the optical path shortening layer 50, and the second light-transmitting layer 22b provided in the phase-difference detection pixel 20 provided in a region requiring pupil correction having a high image height from the center of the pixel array 110 may each have different pupil correction amounts. The optical path shortening layer 50 may be provided only in the phase-difference detection pixel 20 provided in the region requiring pupil correction having a high image height from the center of the pixel array 110.

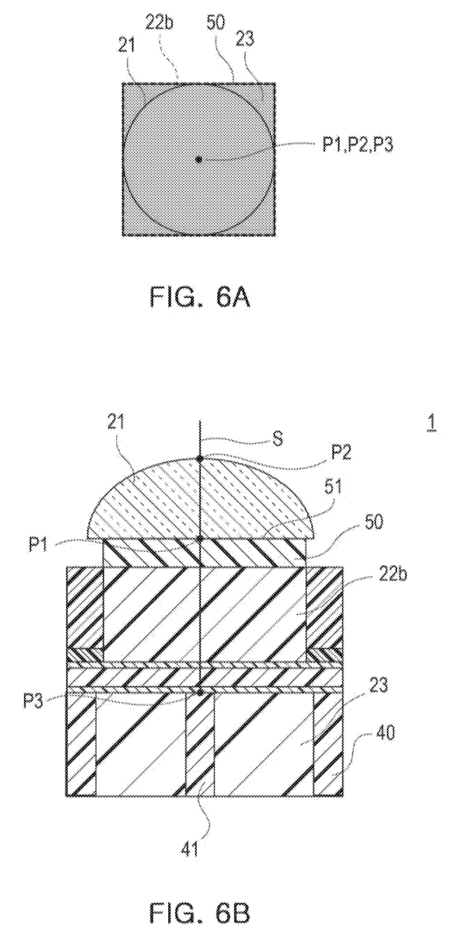

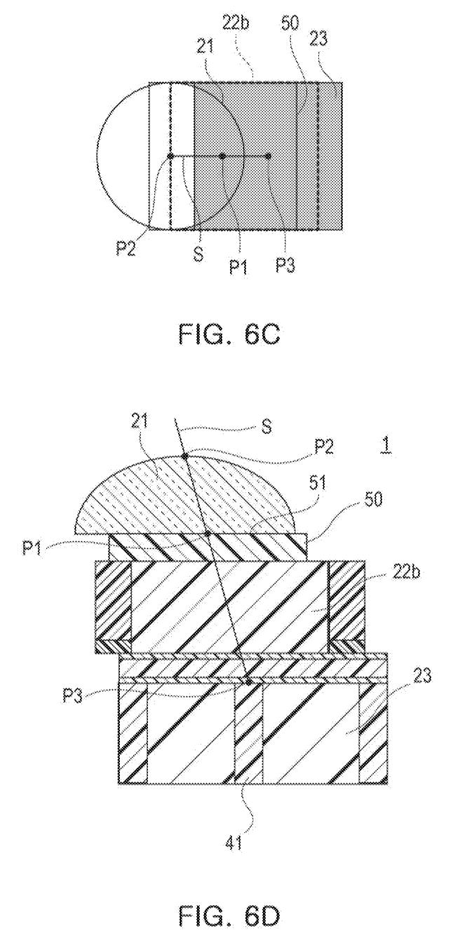

FIGS. 6A and 6B illustrate a phase-difference detection pixel 20 provided in the center 110a of the pixel array 110 according to an embodiment. FIGS. 6C and 6D illustrate a phase-difference detection pixel 20 provided in the peripheral part 110b of the pixel array 110 according to an embodiment. FIGS. 6A and 6C are schematic diagrams viewed in a plan view direction, and FIGS. 6B and 6D are cross-sectional schematic diagrams.

In the phase-difference detection pixel 20 illustrated in FIGS. 6A and 6B, in a position of the solid-state image sensor 1 that does not require pupil correction, a center P1 of the second on-chip lens 21, a center P2 of the optical path shortening layer 50 and a center P3 of second light-transmitting layer 22b may be provided to overlap each other in a stacking direction (X-axis direction) of the solid-state image sensor 1. Meanwhile, in a position of the solid-state image sensor 1 that does require pupil correction, as shown in FIGS. 6C and 6D, the center P1 of the second on-chip lens 21, the center P2 of the optical path shortening layer 50 and the center P3 of second light-transmitting layer 22b may not overlap each other in the stacking direction (X-axis direction) of the solid-state image sensor 1. For example, the center P1 of the second on-chip lens 21, the center P2 of the optical path shortening layer 50 and the center P3 of second light-transmitting layer 22b may be shifted in the stacking direction (X-axis direction) of the solid-state image sensor 1. For example, as shown in FIGS. 6C and 6D, the center P1 when viewed from the plane of the incident surface 51 may be provided on a straight line S connecting the center P2 when viewed from the plane of the second on-chip lens 21 and the center P3 when viewed from the plane of the phase-difference detection pixel 20. In addition, in the solid-state image sensor 1, as shown in FIGS. 6C and 6D, the second on-chip lens 21, the optical path shortening layer 50 and the second light-transmitting layer 22b may each have different pupil correction amounts.

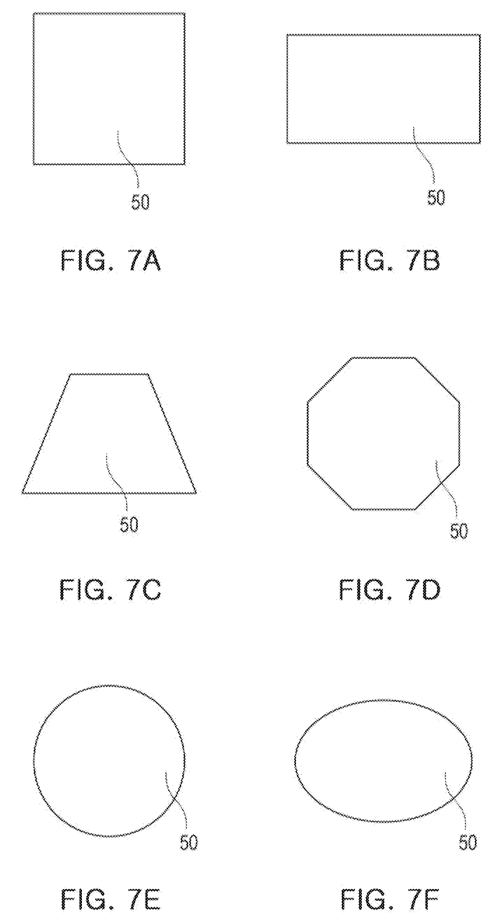

The optical path shortening layer 50, as illustrated in FIGS. 7A, 7B, 7C, 7D, 7E, and 7F, may have any one of the following shapes when viewed from the plane: a square (see FIG. 7A), a rectangle FIG. 7B), a trapezoid (see FIG. 7C), a polygon (see FIG. 7D), a circle (see FIG. 7E), or an ellipse (see FIG. 7F).

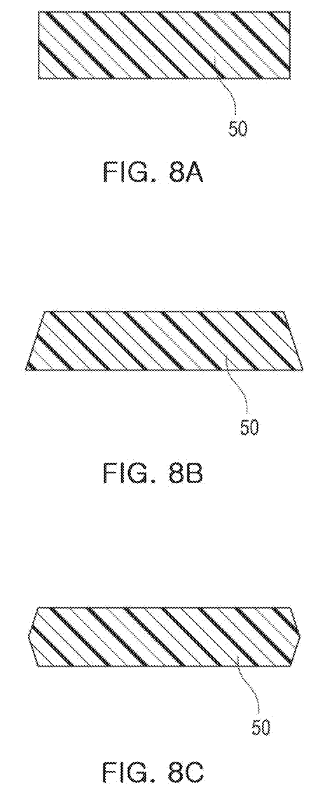

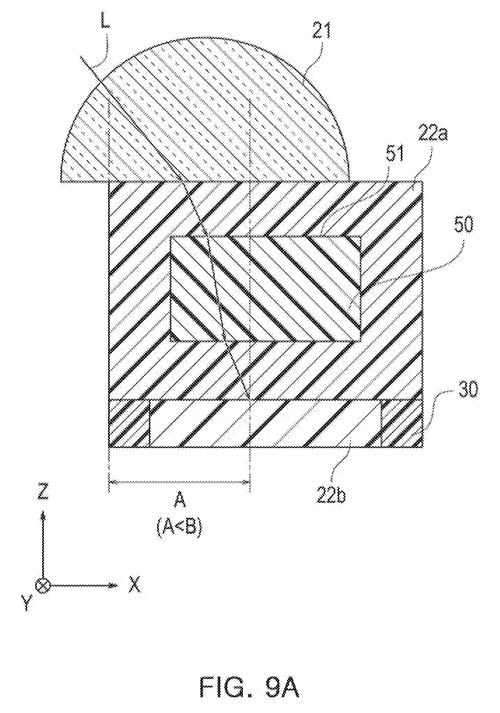

The optical path shortening layer 50, as illustrated in FIGS. 8A, 8B, and 8C, may have any one of the following shapes in terms of a cross-section: a rectangle (see FIG. 8A), a trapezoid (see FIG. 8B), or a polygon (see FIG. 8C).

However, the optical path shortening layer 50 is not limited to the shapes when viewed from each plane illustrated in FIGS. 7A, 7B, 7C, 7D, 7E, and 7F and the cross-sectional shape illustrated in FIGS. 8A, 8B, and 8C, and may have other shapes. In addition, in the optical path shortening layer 50, at least one of a width and a thickness of the cross-sectional shape may be increased according to the image height from the center of the pixel array 110 in which the phase-difference detection pixels 20 are provided so that the reduction of a sensitivity difference is more effectively exerted.

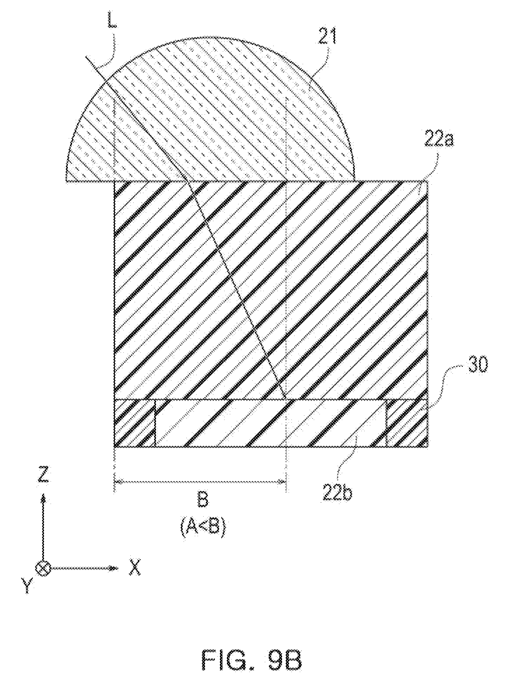

FIG. 9A illustrates a cross-sectional schematic diagram of a solid-state image sensor 1 according to an example embodiment, and the optical path shortening layer 50 is formed inside the second planarizing layer 22a. FIG. 9B illustrates a cross-sectional schematic diagram of a related art phase-difference detection pixel 20 in which the optical path shortening layer 50 is not provided in the solid-state image sensor 1. In addition, FIG. 9A illustrates an optical path length A (arrow A in the drawing) when viewed from the plane of the incident light L, and FIG. 9b illustrates an optical path length B (arrow B in the drawing) when viewed from the plane of the incident light L.

The optical path shortening layer 50 may cause a large refraction of the incident light L that passes through the second on-chip lens 21 and reaches the incident surface 51 of the optical path shortening layer 50, as illustrated in FIG. 9A. The incident light L refracted by the optical path shortening layer 50 may proceed toward the second light-transmitting layer 22b after passing through the optical path shortening layer 50. On the other hand, as illustrated in FIG. 9B, in the case of the configuration in which the optical path shortening layer 50 is not provided, the incident light L may be incident without being refracted. Comparing FIG. 9A and FIG. 9B, as illustrated in FIG. 9A, the incident light L on the phase-difference detection pixel 20 in which the optical path shortening layer 50 may have a shorter optical path length when viewed from the plane than the incident light L incident on the phase-difference detection pixel 20 illustrated in FIG. 9B, so that there may be an optical path length A less than an optical path length B.

In this manner, the solid-state image sensor 1 may greatly refract the incident light L incident on the phase-difference detection pixel 20 by an action of the optical path shortening layer 50, and may make an incident angle of the incident light L (e.g., an incident angle within the optical path shortening layer 50) close to the incident angle of the incident light L for the phase-difference detection pixel 20 on a center side of the pixel array 110 (e.g., the incident angle within the optical path shortening layer 50). In other words, the incident angle of the incident light L on the outer side of the pixel array 110 (the incident angle within the optical path shortening layer 50) may be made smaller than the incident angle within the planarizing layer 22a of FIG. 9B. Accordingly, a difference in pupil correction amount between the phase-difference detection pixel 20 provided at the center 110a of the pixel array 110 and the phase-difference detection pixel 20 provided at the peripheral 110b may be reduced. Accordingly, in the solid-state image sensor 1, since the degree to which the second on-chip lens 21 of the phase-difference detection pixel 20 overlaps the adjacent pixel 10 is suppressed, a sensitivity difference of the pixel 10 around the phase-difference detection pixel 20 may be reduced.

Next, a modified example of the solid-state image sensor according to an example embodiment will be described. Meanwhile, in the form of each modified example illustrated below, the same reference numerals are given to the same component as in the above-described example embodiment, and the description thereof is omitted. In addition, for matters not specifically mentioned, the same configuration as in the above-described example embodiment may be performed. Furthermore, each modified example illustrated below may be appropriately combined with other forms without departing from the gist of the invention.

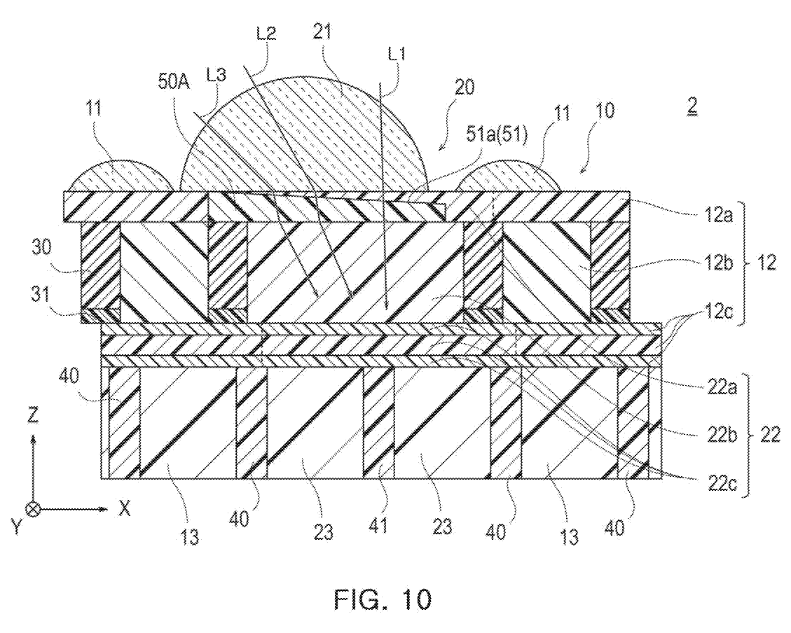

In FIG. 10, a solid-state image sensor 2 of modified example 1 is illustrated. As illustrated in FIG. 10, the solid-state image sensor 2 of modified example 1 is provided with an optical path shortening layer 50A, and the optical path shortening layer 50A may be formed inside the second planarizing layer 22a.

As illustrated in FIG. 10, a thickness of the optical path shortening layer 50A may vary. For example, a first thickness of the optical path shortening layer 50A at a first location may be different from a second thickness of the optical path shortening layer 50A at a second location. For example, the optical path shortening layer 50A may have an inclination surface 51a inclined such that a thickness of the optical path shortening layer 50A gradually increases in a direction in which an incident angle increases with respect to the incident light L. For example, the optical path shortening layer 50A has a first thickness with respect to incident light L1, a second thickness with respect to incident light L2, and a third thickness with respect to incident light L3. Here, an incident angle of the incident light L2 is greater than an incident angle of the incident light L1, and an incident angle of the incident light L3 is greater than the incident angle of the incident light L2, and the second thickness is greater than the first thickness, and the third thickness is greater than the second thickness. The inclination surface 51a may have an inclination angle (gradient) according to the arrangement position of the corresponding phase-difference detection pixel 20 on the pixel array 110. The inclination surface 51a may function as the incident surface 51.

Since the solid-state image sensor 2 of modified example 1 is provided with an optical path shortening layer 50A having the inclination surface 51a, such that the thickness of the optical path shortening layer 50A gradually increases in the direction in which the incident angle of the incident light L increases, the refraction of the incident light L may be further increased. Accordingly, the solid-state image sensor 2 may further reduce the pupil correction amount of the second on-chip lens 21.

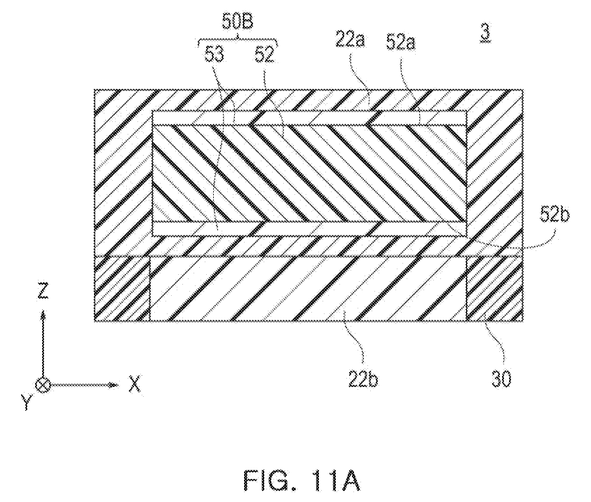

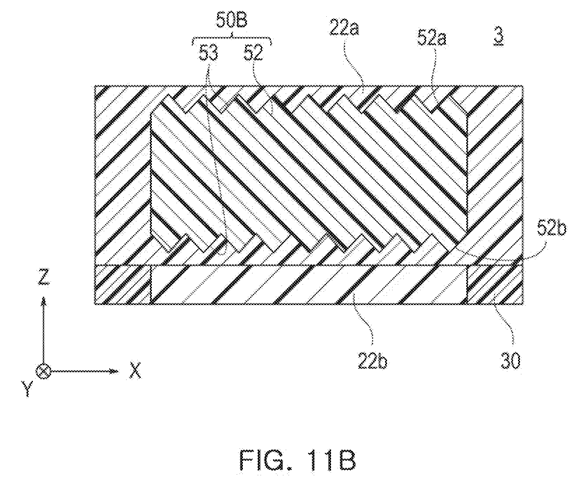

FIGS. 11A and 11B illustrate a solid-state image sensor 3 of modified example 2. The solid-state image sensor 3 of modified example 2 is provided with an optical path shortening layer 50B, and the optical path shortening layer 50B may be formed inside the second planarizing layer 22a.

The optical path shortening layer 50B may include a high refractive index portion 52 and an anti-reflection portion 53. In the optical path shortening layer 50B, the anti-reflection portion 53 is formed on the high refractive index portion 52 in order to reduce a difference in refractive index with the second on-chip lens 21.

The high refractive index portion 52 may form a layer body of the optical path shortening layer 50B. The high refractive index portion 52 may have a first surface 52a on which the incident light L is incident and a second surface 52b opposite to the first surface 52a. According to an embodiment, entire layers (or all layers) of the optical path shortening layers 50 and 50A having the above-described form may be formed of the high refractive index portion 52.

The anti-reflection portion 53 may be provided on at least a portion of the first surface 52a and at least a portion of the second surface 52b of the high refractive index portion 52. For example, the anti-reflection portion 53 may be formed to cover at least the first surface 52a and the second surface 52b of the high refractive index portion 52. The anti-reflection portion 53 may include an anti-reflection film formed of a material causing an anti-reflection effect, such as SiO₂, as illustrated in FIG. 11A. The anti-reflection film may have a film thickness according to an arrangement position of the phase-difference detection pixel 20 on the pixel array 110, and the like. The anti-reflection portion 53 may have an anti-reflection structure causing an anti-reflection effect, as illustrated in FIG. 11B. For example, as illustrated in FIG. 11B, the anti-reflection structure may have peak and value portions, or concave and convex portions. For example, the anti-reflection structure may have a surface with alternatingly raised and recessed sections, forming a pattern of sharp peaks and valleys. The shape of the anti-reflection structure is not limited as long as the anti-reflection structure is a structure suppressing reflection of light, such as a rough shape.

The anti-reflection portion 53 may be formed to cover at least the first surface 52a and the second surface 52b of the high refractive index portion 52, as illustrated in FIGS. 11A and 11B, thus reducing unintended reflection of incident light L. According to an embodiment, the anti-reflection portion 53 may be provided on an entire circumference of the high refractive index portion 52. For example, the anti-reflection portion 53 may be formed to cover an entire circumference of the high refractive index portion 52, so that the anti-reflection effect may be more efficiently exerted.

Since the solid-state image sensor 3 of modified example 2 forms the anti-reflection portion 53 on the high refractive index portion 52 of the optical path shortening layer 50B, unintended reflection of incident light L incident on the optical path shortening layer 50B may be reduced, thereby reducing a difference in refractive index from the second on-chip lens 21.

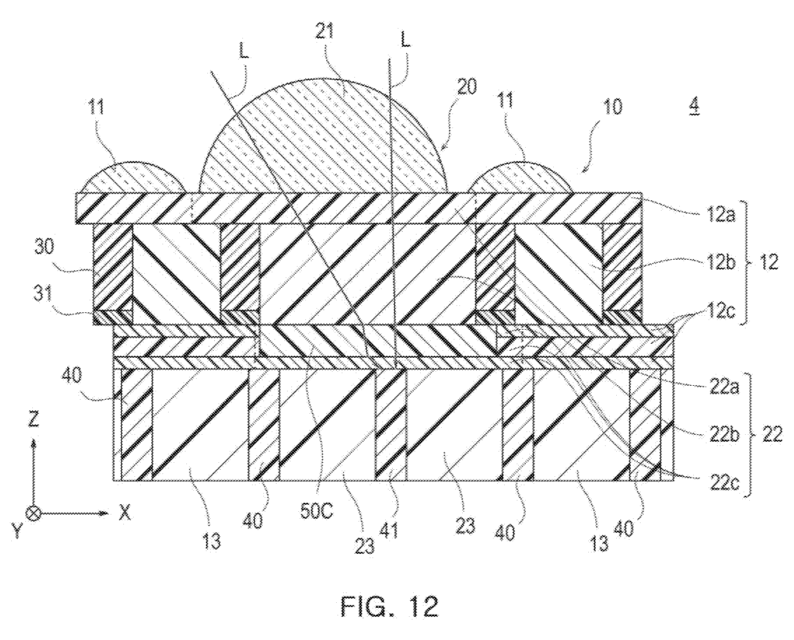

FIG. 12 illustrates a solid-state image sensor 4 of modified example 3. The solid-state image sensor 4 of modified example 3 may be provided with an optical path shortening layer 50C. The optical path shortening layer 50C may be provided between the second light-transmitting layer 22b and the second photoelectric converter 23. The optical path shortening layer 50C may be provided inside the second anti-reflection layer 22c between the second light-transmitting layer 22b and the second photoelectric converter 23, as illustrated in FIG. 12. Alternatively, the optical path shortening layer 50C may be provided between the second light-transmitting layer 22b and the second photoelectric converter 23 instead of the second anti-reflection layer 22c.

The solid-state image sensor 4 of modified example 3 may reduce a difference between the pupil correction amount of the second on-chip lens 21 and the pupil correction amount of the pixel 10 by refracting the incident light L, by providing the optical path shortening layer 50C between the second light-transmitting layer 22b and the second photoelectric converter 23. Accordingly, in the solid-state image sensor 4, since the degree to which the second on-chip lens 21 of the phase-difference detection pixel 20 overlaps the adjacent pixel 10 is suppressed, the sensitivity difference of the pixels 10 around the phase-difference detection pixel 20 may be reduced.

As described above, the solid-state image sensor 1 according to the disclosure may include a pixel array 110 in which a plurality of pixels 10 generating an electric signal according to incident light L and a plurality of phase-difference detection pixels 20 are arranged two-dimensionally, and the pixel 10 may include a first photoelectric converter 13, a first on-chip lens 11 provided on an incident side of the incident light L in the first photoelectric converter 13, and a first light-transmitting layer 12b transmitting light having a specific wavelength in the incident light L, and the phase-difference detection pixel 20 may include a second photoelectric converter 23, a second on-chip lens 21 provided on the incident side of the incident light L in the second photoelectric converter 23 and having a greater diameter than that of the first on-chip lens 11, and a second light-transmitting layer 22b transmitting light having a specific wavelength in the incident light L, and the phase-difference detection pixel 20 may be provided with an optical path shortening layer 50 provided between the second on-chip lens 21 and the second photoelectric converter 23, the optical path shortening layer 50 may have an incident surface 51 on which incident light L is incident and may have a refractive index higher than that of other adjacent films, and the second on-chip lens 21, the optical path shortening layer 50, and the second optical path shortening layer 22b provided in the phase-difference detection pixel 20 provided in a region requiring high pupil correction having a high image height from the center of the pixel array 110 may each have different pupil correction amounts.

By such a configuration, the solid-state image sensor 1 may be provided with an optical path shortening layer 50 refracts incident light L incident within the phase-difference detection pixel 20, thereby making an incident angle of the incident light L (e.g., an incident angle within the optical path shortening layer 50) close to the incident angle of the incident light L (e.g., an incident angle within the optical path shortening layer 50) for the phase-difference detection pixel 20 on a central side of the pixel array 110. For example, the optical path shortening layer 50 refracts incident light L incident within the phase-difference detection pixel 20 at a greater amount than the second light-transmitting layer 22. Accordingly, a difference in the pupil correction amount between the phase-difference detection pixel 20 provided on the central side of the pixel array 110 and the phase-difference detection pixel 20 provided on an outer side may be reduced. Accordingly, since the degree to which the second on-chip lens 21 of the phase-difference detection pixel 20 overlaps the adjacent pixel 10 is suppressed in the solid-state image sensor 1, the sensitivity difference of the pixels 10 surrounding the phase-difference detection pixel 20 may be reduced.

Next, an example embodiment of the disclosure will be described, but the disclosure is not limited to the following example embodiment.

Hereinafter, a simulation performed to evaluate the sensitivity difference between a plurality of green pixels adjacent to the phase-difference detection pixels of the solid-state image sensor (in the case of the example embodiment) of the disclosure and a related art solid-state image sensor (in the case of the comparative example) is described. The simulation calculated the quantum efficiency in the photoelectric converter of the plurality of green pixels by the Finite-Difference Time-Domain method (FDTD method) using Rsoft (manufactured by Synopsys). A wavelength used in the calculation was 530 nm. The optical path shortening layer was formed using TiO₂ as a forming material, had a thickness of 0.14 μm, a width of 70% of the pixel pitch, and a pupil correction amount of 30% of the pixel pitch.

The sample of the example embodiment was configured as a solid-state image sensor according to the disclosure, in which the optical path shortening layer was provided between the on-chip lens and the light-transmitting layer, as illustrated in FIG. 2B. The sample of the comparative example was configured as a related art solid-state image sensor in which the optical path shortening layer was not provided, that is, the configuration excluding the optical path shortening layer from the configuration illustrated in FIG. 2B.

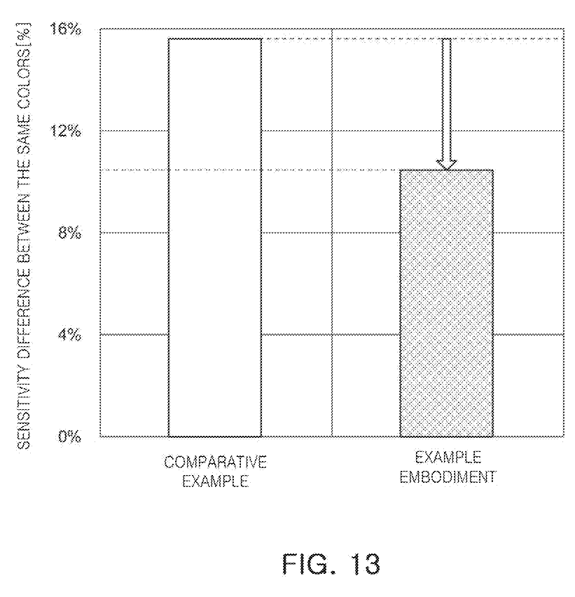

FIG. 13 illustrates a graph illustrating a simulation result of a sensitivity difference between the same color in the example embodiment and the comparative example. As illustrated in FIG. 13, when comparing the example embodiment and the comparative example, it was confirmed that the sensitivity difference of the pixels was reduced in the example embodiment.

From the results, in the solid-state image sensor, disposing an optical path shortening layer refract incident light and shortening an optical path length between the on-chip lens (e.g., the second on-chip lens) of the phase-difference detection pixel and the photoelectric converter (e.g., the second photoelectric converter) represents an effective element for reducing the sensitivity difference between pixels adjacent to the phase-difference detection pixel.

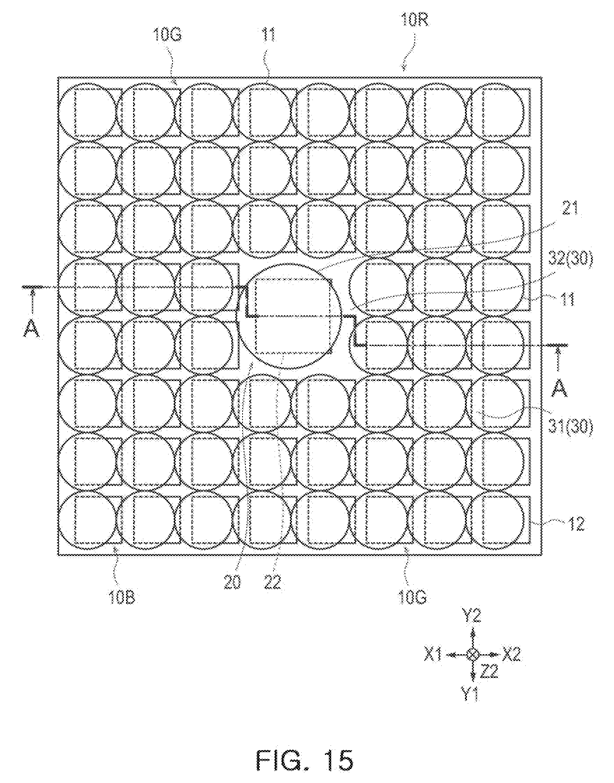

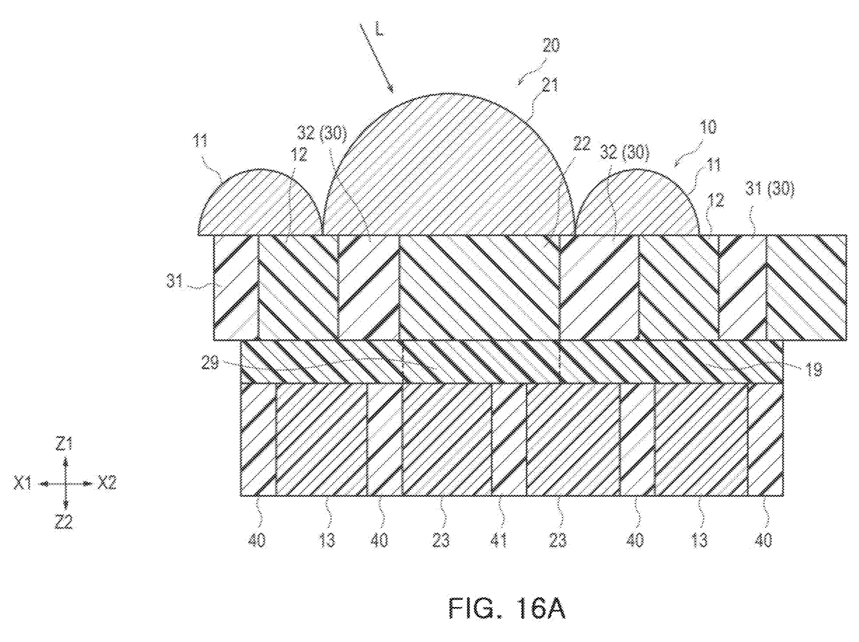

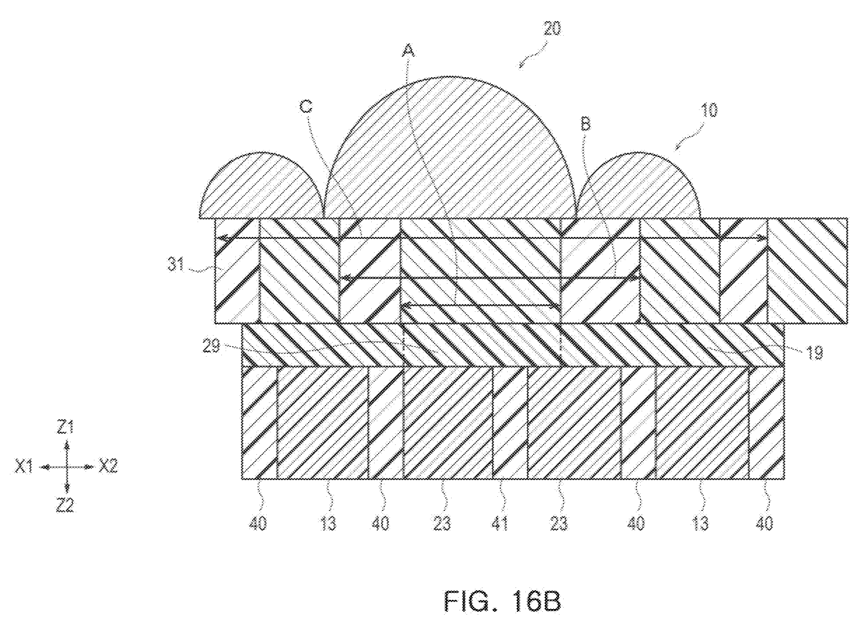

FIG. 15 illustrates a plan view of a portion of the solid-state image sensor 1 according to the example embodiment, and FIG. 16A illustrates a cross-sectional view taken along line A-A of FIG. 15.

The pixel 10 may include a red pixel 10R, a green pixel 10G, and a blue pixel 10B, as illustrated in FIG. 15. The pixel 10 may be arranged in a two-dimensional shape (for example, in a matrix shape) on a chip substrate 100. The arrangement of the pixel 10 may be appropriately set according to the specifications of the solid-state image sensor 1.

As illustrated in FIG. 16A, the pixel 10 may include, in order from the incident side of the incident light L, a first on-chip lens 11, a first light-transmitting layer 12, and a first photoelectric converter 13. The pixel 10 is independently isolated from the adjacent pixel 10 or the phase-difference detection pixel 20 by the first separation wall 31 and the second separation wall 32 of the light-transmitting layer separation wall 30 or the pixel separation wall 40.

The first on-chip lens 11 may be formed on the first light-transmitting layer 12. The first on-chip lens 11 may be arranged to correspond to each pixel 10. For example, the first on-chip lens 11 may be arranged two-dimensionally (for example, in a matrix shape) on a plane. The first on-chip lens 11 may have a convex shape and a predetermined radius of curvature so that incident light L is focused on the first photoelectric converter 13. The first on-chip lens 11 may be formed using an organic material such as a styrene-based resin, an acrylic-based resin, a styrene-acrylic copolymer resin, or a siloxane-based resin, for example.

The first light-transmitting layer 12 may be formed between the first on-chip lens 11 and the first photoelectric converter 13. The first light-transmitting layer 12 may be arranged two-dimensionally (for example, in a matrix shape) to correspond to each unit pixel. The first light-transmitting layer 12 may have a function of transmitting light having a specific wavelength in a visible light range. Accordingly, the first light-transmitting layer 12 may function as a variety of color filters for each unit pixel.

The first light-transmitting layer 12 may function as a red color filter transmitting red light having a specific wavelength to correspond to a red pixel 10R and absorbing green light and blue light. In addition, the first light-transmitting layer 12 may function as a green color filter transmitting green light having a specific wavelength to correspond to a green pixel 10G and absorbing red light and blue light. In addition, the first light-transmitting layer 12 may function as a blue color filter transmitting blue light having a specific wavelength to correspond to the blue pixel 10B and absorbing red light and green light.

The first light-transmitting layer 12 may be provided in a Bayer pattern including first light-transmitting layers 12 corresponding to the red pixel 10R, the green pixel 10G and the blue pixel 10B. However, this is exemplary, and the first light-transmitting layer 12 may also include a yellow filter, a magenta filter, and a cyan filter. The first light-transmitting layer 12 may be formed by including a pigment or dye of a desired color in a resin having low light absorption.

A first separation wall 31 having light-blocking properties may be formed at a boundary between the first light-transmitting layer 12 and an adjacent first light-transmitting layer 12. In addition, a second separation wall 32 having a light-blocking property may be formed at a boundary between the first light-transmitting layer 12 and the second light-transmitting layer 22 of the adjacent phase-difference detection pixel 20. As a result, the first light-transmitting layers 12 may be separated for each pixel, between the adjacent pixels 10 or between the pixels 10 and the phase-difference detection pixels 20.

As illustrated in FIG. 16A, X-direction thicknesses of the first light-transmitting layer 12 of the pixel 10 adjacent to the left of the phase-difference detection pixel 20 in the X-direction and the first light-transmitting layer 12 of the pixel 10 adjacent to the right of the phase-difference detection pixel 20 in the X-direction may be approximately the same.

Meanwhile, a first planarizing layer may be formed between the first light-transmitting layer 12 and the first on-chip lens 11. The first planarizing layer has a high transmittance for light incident on the first photoelectric converter 13 and provides a flat formation surface for the first on-chip lens 11. The first planarizing layer may be formed of, for example, an organic material such as a resin.

In addition, a first anti-reflection layer 19 may be formed between the first light-transmitting layer 12 and the first photoelectric converter 13. The first anti-reflection layer 19 may include an appropriate combination of a high-refractive material (e.g., SiN, HfO, TaO, TiO, or the like) and a low-refractive material (SiO₂, or the like).

The first photoelectric converter 13 may convert transmitted light of the photoelectric conversion target progressing to the first photoelectric converter 13, among the incident light L incident on the pixel 10, into an electric signal. The first photoelectric converters 13 may be separated by the pixel separation wall 40 to be separated for each pixel, between the adjacent pixels 10 or between the pixels 10 and the phase-difference detection pixels 20. The first photoelectric converter 13 may include, for example, at least one of a photo diode, a photo transistor, a photo gate, a pinned photo diode, an organic photo diode, a quantum dot, and combinations thereof, but the disclosure is not limited thereto.

As illustrated in FIG. 16A, the phase-difference detection pixel 20 may include, in order from the incident side of the incident light L, a second on-chip lens 21, a second light-transmitting layer 22, and a second photoelectric converter 23. The phase-difference detection pixel 20 may be independently separated from the adjacent pixel 10 by the second separation wall 32 of the light-transmitting layer separation wall 30 or the pixel separation wall 40.

The phase-difference detection pixel 20 may have a structure in which the second photoelectric converter 23 is separated into a plurality of parts by the boundary separation wall 41. The phase-difference detection pixel 20 may calculate the amount of focus misalignment from a phase difference of the image surface acquired from the multiple pixels 10 and may implement autofocus. Accordingly, the image sensor equipped with the solid-state image sensor 1 may focus on a subject based on a phase difference of the light incident on the pixel 10 without requiring a mechanism dedicated to autofocus.

The second on-chip lens 21 may be formed on the second light-transmitting layer 22. The second on-chip lens 21 may be arranged to correspond to each phase-difference detection pixel 20. The second on-chip lens 21 may have a greater diameter than that of the first on-chip lens 11. The second on-chip lens 21 may have different sizes, such as a diameter or height in a planar view, but may be formed of the same material as the first on-chip lens.

The second light-transmitting layer 22 may be formed between the second on-chip lens 21 and the second photoelectric converter 23. The second light-transmitting layer 22 may transmit light having a specific wavelength photoelectrically converted in the second photoelectric converter 23.

The second light-transmitting layer 22 may function as a red color filter, a green color filter or a blue color filter, similarly to the first light-transmitting layer 12 described above. The second light-transmitting layer 22 may have the same forming materials as the first light-transmitting layer 12.

A second separation wall 32 having light-blocking properties may be formed at a boundary between the second light-transmitting layer 22 and the first light-transmitting layer 12 of the adjacent pixel 10. Accordingly, the second light-transmitting layers 22 may be separated for each pixel, between the adjacent pixels 10.

As illustrated in FIGS. 14 and 15, in an outer peripheral portion of the pixel array 110, the second light-transmitting layer 22 of the phase-difference detection pixel 20 may be provided so as to be shifted toward a side projected on the plane of an incident direction of the incident light. For example, the second light-transmitting layer 22 may be provided so as to be shifted toward the left side of FIG. 14 and FIG. 15.

Meanwhile, a second planarizing layer may be formed between the second light-transmitting layer 22 and the second on-chip lens 21. The second planarizing layer may include the same material as the first planarizing layer.

In addition, a second anti-reflection layer 29 may be formed between the second light-transmitting layer 22 and the second photoelectric converter 23. The second anti-reflection layer 29 may include the same material as the first anti-reflection layer 19. The second anti-reflection layer 29 and the first anti-reflection layer 19 may be formed integrally or may be configured separately. However, the disclosure is not limited thereto, and as such, the second anti-reflection layer 29 and the first anti-reflection layer 19 may be different.

The second photoelectric converter 23 may convert transmitted light of the photoelectric conversion target progressing to the second photoelectric converter 23 among the incident light L incident on the phase-difference detection pixel 20, into an electric signal. The second photoelectric converters 23 may be separated by the pixel separation wall 40 to be separated between the adjacent pixel 10. The second photoelectric converter 23 may have the same forming materials as the first photoelectric converter 13.

The phase-difference detection pixel 20 may have a greater device size than that of the pixel 10. A pixel size of the phase-difference detection pixel 20 may have a length of two pixels of the pixel 10 in a horizontal direction along the X-axis direction (e.g., first direction), as illustrated in FIG. 15, and a length of two pixels of the pixel 10 in a vertical direction along the Y-axis direction (e.g., second direction). Meanwhile, the X-axis direction may be the second direction and the Y-axis direction may be the first direction.

As illustrated in FIG. 16A, the light-transmitting layer separation wall 30 may include a first separation wall 31 separating first light-transmitting layers 12 adjacent to each other, and a second separation wall 32 separating the adjacent first light-transmitting layers 12 and the second light-transmitting layers 22. As illustrated in FIG. 15, the first separation wall 31 and the second separation wall 32 may be provided in a grid shape, and may form a boundary between the adjacent first light-transmitting layers 12 and the second light-transmitting layers 22, thereby separating each layer into a predetermined size. The light-transmitting layer separation wall 30 may have at least a function of preventing vignetting of incident light L incident on the pixel 10 and a function of blocking incoming light from the adjacent pixel 10. Accordingly, the light-transmitting layer separation wall 30 may be formed to have a height and a width satisfying these functions. The light-transmitting layer separation wall 30 may include a dielectric having low light absorption, such as SiO₂ or SiN. In addition, the second separation wall 32 may also include a dielectric having low light absorption, such as SiO₂ or SiN.

In the solid-state image sensor 1 according to an example embodiment, in an outer peripheral portion of the pixel array 110 (see symbol A in FIG. 14), the pupil correction amount of the second light-transmitting layer 22 in the phase-difference detection pixel 20 may be greater than the pupil correction amount of the second separation wall 32 of the phase-difference detection pixel 20. That is, as illustrated in FIG. 16B, the pupil correction amount of the second light-transmitting layer 22 in a range indicated by a double arrow A may be on average greater than the pupil correction amount of the second separation wall 32 in a range indicated by a double arrow B. That is, a center of the range indicated by the double arrow A may be shifted and provided to a side projected on a plane of an incident direction of incident light as compared to a center of the range indicated by the double arrow B.

In the solid-state image sensor 1 according to an example embodiment, in an outer peripheral portion of the pixel array 110 (see FIG. 14), the pupil correction amount of the second light-transmitting layer 22 in the phase-difference detection pixel 20 may be greater than the pupil correction amount of the first separation wall 31 of the pixel 10 adjacent to the phase-difference detection pixel 20. That is, as illustrated in FIG. 16B, the pupil correction amount of the second light-transmitting layer 22 in the range indicated by the double arrow A may be greater on average than the pupil correction amount of the first separation wall 31 in a range indicated by a double arrow C. That is, the center of the range indicated by the double arrow A may be shifted and provided to the side projected on the plane of the incident direction of the incident light as compared to a center of the range indicated by the double arrow C.

As illustrated in FIG. 16A, the second separation wall 32 provided between the second light-transmitting layer 22 and the first light-transmitting layer 12 on the right, and the second separation wall 32 provided between the second light-transmitting layer 22 and the first light-transmitting layer 12 on the left may have different thicknesses in the X-direction.

The pixel separation wall 40 may be formed with Deep Trench Isolation (DTI). As illustrated in FIG. 16A, the pixel separation wall 40 may be formed to surround the first photoelectric converter 13 of the pixel 10 or the second photoelectric converter 23 of the phase-difference detection pixel 20. Accordingly, the first photoelectric converter 13 of the pixel 10 and the second photoelectric converter 23 of the phase-difference detection pixel 20 may be separated from another pixel 10 or another phase-difference detection pixel 20 adjacent thereto.

The pixel separation wall 40 may separate the first photoelectric converter 13 or the second photoelectric converter 23 by a unit pixel size. The pixel separation wall 40 may independently separate the second photoelectric converters 23 of the phase-difference detection pixels 20 into a predetermined number.

The boundary separation wall 41 may separate the second photoelectric converter 23 of the phase-difference detection pixels 20 into a plurality of parts. Within in the second photoelectric converter 23, the boundary separation wall 41 may separate the second photoelectric converter 23 so that the phase difference of the image surface may be detected within the phase-difference detection pixel 20.

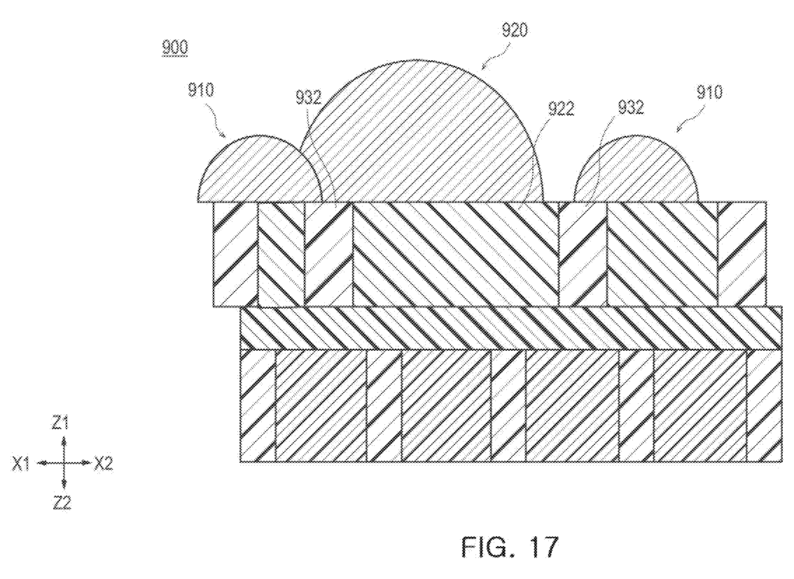

Next, referring to FIG. 17, the configuration of a solid-state image sensor 900 according to a comparative example will be described. As illustrated in FIG. 17, in the solid-state image sensor 900 according to the comparative example, a pupil correction amount of a second light-transmitting layer 922 in a phase-difference detection pixel 920 is configured to be approximately the same as a pupil correction amount of a second separation wall 932 of the phase-difference detection pixel 920. Accordingly, a pair of second separation walls 932 adjacent to the second light-transmitting layer 922 have approximately the same thickness. In this configuration, since there is a difference in the thickness of the first light-transmitting layer of the phase-difference detection pixel 920 and an adjacent pixel 910 in the X-direction, there is a case in which the solid-state image sensor 900 significantly deteriorates the image quality due to color mixing or sensitivity reduction at a boundary of the pixel 910 adjacent to the phase-difference detection pixel 920.

In contrast, in the solid-state image sensor 1 according to an example embodiment, as illustrated in FIGS. 15A and 16A, the pupil correction amount of the second light-transmitting layer 22 in the phase-difference detection pixel 20 of the outer peripheral portion of the pixel array 110 may be greater than the pupil correction amount of the second separation wall 32 of the phase-difference detection pixel 20. For this reason, a pair of second separation walls 32 adjacent to the second light-transmitting layer 22 may have asymmetrical thicknesses in the X-direction, while a pair of first light-transmitting layers 12 of the pixels 10 adjacent to the phase-difference detection pixel 20 may have approximately the same thicknesses in the X-direction. That is, within the phase-difference detection pixel 20, by appropriately changing the thickness of the second separation wall 32 according to a difference between the pupil correction amount of the second light-transmitting layer 22 and the pupil correction amount of the second separation wall 32, the light collection efficiency of the incident light L in a pair of pixels 10 may be improved. Accordingly, a sensitivity difference between the pixels 10 adjacent to the phase-difference detection pixel 20 may be reduced.

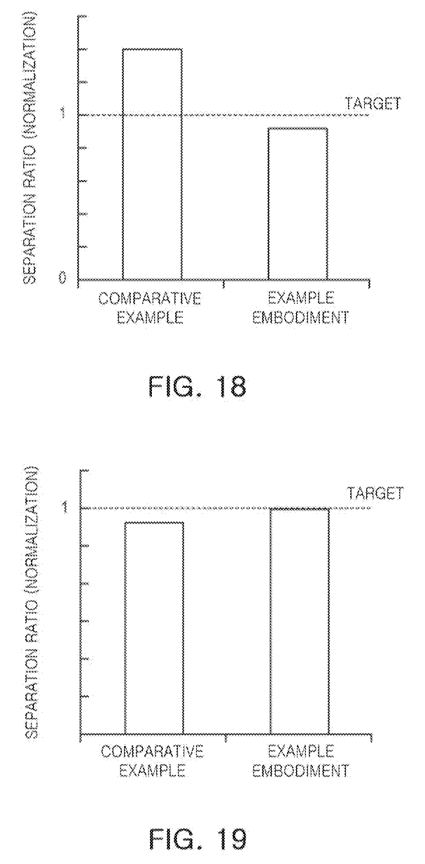

Next, with reference to FIG. 18, a simulation result of the solid-state image sensor 1 according to the example embodiment and the solid-state image sensor 900 according to the comparative example will be described.

For example, a simulation was conducted to evaluate a sensitivity difference between a plurality of same-color pixels adjacent to the phase-difference detection pixels of the solid-state image sensor 1 according to the example embodiment and the solid-state image sensor 900 according to the comparative example, and a simulation was conducted to obtain a separation ratio of the solid-state image sensor 1 according to the example embodiment and the solid-state image sensor 900 according to the comparative example was conducted.

In FIG. 18, a graph illustrating the simulation results of the sensitivity difference between same colors of the solid-state image sensors according to the present example and the comparative example is shown. In addition, FIG. 19, a graph illustrating the simulation results of the separation ratio of the solid-state image sensors according to the inventive example and the comparative example is shown. As illustrated in FIG. 18, when comparing the sensitivity differences between same colors of the solid-state image sensors according to the example embodiment and the solid-state image sensor according to the comparative example, it was confirmed that the solid-state image sensor according to the example embodiment may reduce the sensitivity difference between same colors. In addition, as illustrated in FIG. 19, when comparing the separation ratios of the solid-state image sensor according to the example embodiment and the solid-state image sensor according to the comparative example, it was confirmed that the solid-state image sensor according to the example embodiment was closer to a desired value.

As described above, the solid-state image sensor 1 according to the example embodiment is a solid-state image sensor 1 having a pixel 10 generating an electric signal according to incident light L and a pixel array 110 in which phase-difference detection pixels 20 are arranged in a two-dimensional shape on a chip substrate. The pixel 10 may include a first photoelectric converter 13, a first on-chip lens 11 provided on an incident side of incident light L in the first photoelectric converter 13, a first light-transmitting layer 12 transmitting a specific wavelength and provided between the first on-chip lens 11 and the first photoelectric converter 13, and a first separation wall 31 provided between the first light-transmitting layer 12 adjacent to the first light-transmitting layer 12. The phase-difference detection pixel 20 may include a second photoelectric converter 23, a second on-chip lens 21 provided on the incident side of the incident light L in the second photoelectric converter 23 and having a greater diameter than that of the first on-chip lens 11, a second light-transmitting layer 22 transmitting a specific wavelength and provided between the second on-chip lens 21 and the second photoelectric converter 23, and a second separation wall 32 provided between the first light-transmitting layer 12 adjacent to the second light-transmitting layer 22. In an outer peripheral portion of the pixel array 110, the pupil correction amount of the second light-transmitting layer 22 in the phase-difference detection pixel 20 may be greater than the pupil correction amount of the second separation wall 32 of the phase-difference detection pixel 20.

According to the solid-state image sensor 1 configured as described above, a thickness of the second separation wall 32 of the phase-difference detection pixel 20 may increase toward the inside, thereby improving the light collection efficiency of the incident light L. Accordingly, the sensitivity difference between the pixels 10 adjacent to the phase-difference detection pixel 20 may be reduced.

Next, a modified example of the solid-state image sensor according to an example embodiment will be described. Meanwhile, in the form of each modified example shown below, the same component as that of the above-described embodiment is assigned the same reference numeral and the description thereof is omitted. In addition, for matters not specifically mentioned, the same configuration as that of the above-described embodiment may be performed. Furthermore, each modified example illustrated below may be appropriately combined with other forms without departing from the gist of the invention.

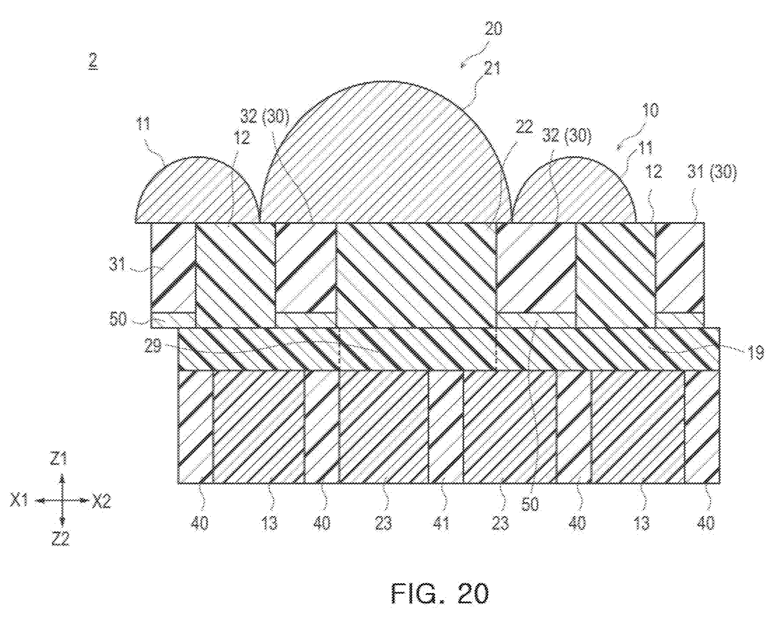

FIG. 20 illustrates a view corresponding to FIG. 16A of the solid-state image sensor 2 according to modified example 1. In the solid-state image sensor 2 according to modified example 1, as illustrated in FIG. 20, a light absorbing material 50 may be provided on bottom surfaces of the first separation wall 31 and the second separation wall 32 so as to have the same thickness in the X-direction as the first separation wall 31 and the second separation wall 32.

In this manner, the light absorbing material 50 may be provided on the bottom surfaces of the first separation wall 31 and the second separation wall 32, so that color mixing between the adjacent pixel 10 and the phase-difference detection pixel 20 may be prevented, and the separation ratio may be improved.

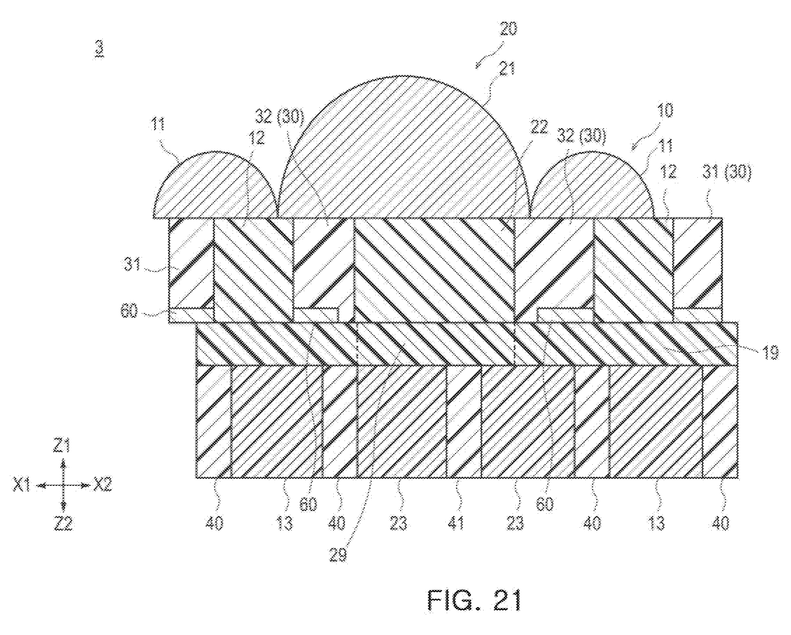

FIG. 21 illustrates a view corresponding to FIG. 16A of the solid-state image sensor 3 according to modified example 2. In the solid-state image sensor 3 according to modified example 2, as illustrated in FIG. 21, a thickness of a light absorbing material 60 provided on the bottom surface of the second separation wall 32 in the X-direction may be configured to be thinner than a thickness of the second separation wall 32 in the X-direction. The light absorbing material 60 may be spaced apart from the second light-transmitting layer 22 by a predetermined distance.

According to such a configuration, as compared to the solid-state image sensor 2 according to modified example 1, absorption of light by the light absorbing material 60 may be suppressed, thereby improving the sensitivity of the phase-difference detection pixel 20.

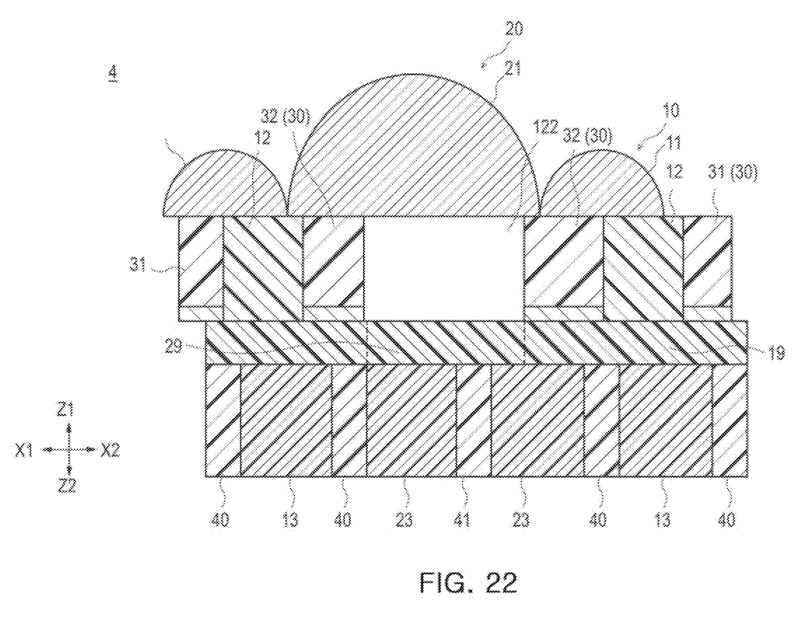

FIG. 22 illustrates a view corresponding to FIG. 16A of the solid-state image sensor 4 according to modified example 3. A second light-transmitting layer 122 of the solid-state image sensor 3 according to modified example 3 may function as a white filter transmitting light having a specific wavelength that is approximately the entire visible light range, as illustrated in FIG. 22.

According to such a configuration, the sensitivity of the phase-difference detection pixel 20 may be improved.

The configuration of the solid-state image sensor has been described through the above-described example embodiments and modified examples, However, the disclosure is not limited to the above-described embodiments, and may be variously modified within the scope of the patent claims.

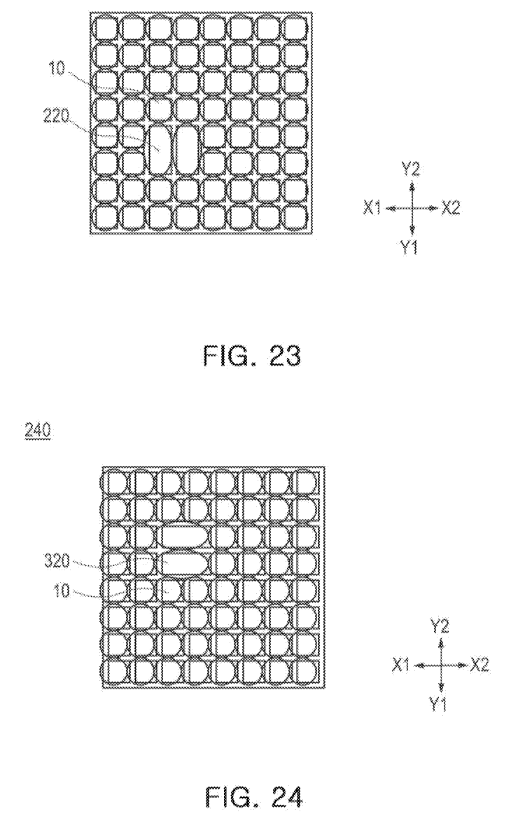

According to one or more example embodiments described above, a pixel size of the phase-difference detection pixel 20 is formed to have a length of two pixels of the pixel 10 in the horizontal direction along the X-axis direction and a length of two pixels of the pixel 10 in the vertical direction along the Y-axis direction. However, a pixel size of a phase-difference detection pixel 220 according to modified example 1 may be formed to have a length of one pixel of the pixel 10 in the horizontal direction along the X-axis direction, as illustrated in FIG. 23, and to have a length of two pixels of the pixel 10 in the vertical direction along the Y-axis direction. Furthermore, a pixel size of a phase-difference detection pixel 320 according to modified example 2 may be formed to have a length of two pixels of the pixel 10 in the horizontal direction along the X-axis direction, as illustrated in FIG. 24, and to have a length of one pixel of the pixel 10 in the vertical direction along the Y-axis direction.

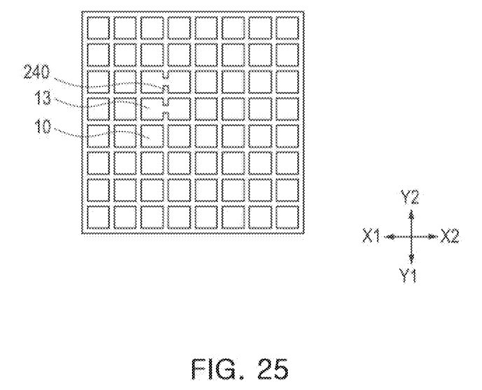

According to one or more example embodiments described above, the pixel separation wall 40 separates the first photoelectric converter 13 or the second photoelectric converter 23 by a unit pixel size. However, a pixel separation wall 240 may be formed so as not to surround a portion of an entire circumference of the first photoelectric converter 13 or the second photoelectric converter 23, as illustrated in FIG. 25. That is, the pixel separation wall 40 may be configured using a boundary separation wall 41 without a separation wall in a central portion of two pixels included in the phase-difference detection pixel 20. Accordingly, although this somewhat affects the spectral characteristics, the noise reduction effect may be improved.

In an example embodiment of FIG. 1B, a center of the boundary separation wall 41 in the phase-difference detection pixel 20 of an outer peripheral portion of the pixel array 110 (see symbol A in FIG. 26) may be provided on an outer peripheral side of the pixel array 110 as compared to a center of the pixel separation wall 40. That is, as illustrated in FIG. 27, a center of the boundary separation wall 41 in the range indicated by the double arrow B may be provided closer to the outer peripheral side of the pixel array 110 than the center of the range of the pixel separation wall 40 indicated by the double arrow A. The boundary separation wall 41 may be provided to be offset from a side opposite to a side projected onto a plane in the incidence direction of the incident light L. Accordingly, a pair of pixel separation walls 40 adjacent to the second photoelectric converter 23 and the first photoelectric converter 13 may be formed to have asymmetrical thicknesses, and the pixel separation wall 40 on a central side of the pixel array 110 (e.g., a side projected onto the plane in the incidence direction of the incident light L) may be formed to be thicker than the pixel separation wall 40 on an outer side of the pixel array 110.

Next, referring to FIG. 17, the configuration of the solid-state image sensor 900 according to the comparative example will be described. In the solid-state image sensor 900 according to the comparative example, a center of a boundary separation wall 941 in the phase-difference detection pixel 920 of an outer peripheral portion of a pixel array is provided so as to approximately coincide with a center of a pixel separation wall 940. In the case of such a configuration, since there is a difference between thicknesses of the first light-transmitting layers of the phase-difference detection pixel 920 and an adjacent pixel 910 in the X-direction, in the solid-state image sensor 900, color mixing or sensitivity reduction may occur at a boundary of the pixel 910 adjacent to the phase-difference detection pixel 920, which may significantly deteriorate the image quality.

In contrast, in the solid-state image sensor 1 according to the example embodiment, a center of the second photoelectric converter separated into a plurality of parts by the boundary separation wall 41 in the phase-difference detection pixel 20 of the outer peripheral portion of the pixel array 110 may be provided on an outer peripheral side of the pixel array as compared to the center of the pixel separation wall 40. Accordingly, even in an example case in which the pupil correction amount of the phase-difference detection pixel is the same as the pupil correction amount of the pixels provided around the phase-difference detection pixel, it may be possible to focus light on the center of the plurality of second photoelectric converters 23, and the on-chip lens of the phase-difference detection pixel and the on-chip lens of the pixel adjacent to the phase-difference detection pixel may be configured to not overlap each other. Accordingly, a sensitivity difference between the phase-difference detection pixel and the adjacent pixel may be reduced.

As described above, the solid-state image sensor 1 according to the example embodiment is a solid-state image sensor 1 having a pixel 10 generating an electric signal according to incident light L, and a pixel array 110 in which the phase-difference detection pixels 20 are arranged in the two-dimensional shape on the chip substrate. The pixel 10 may include a first photoelectric converter 13, a first on-chip lens 11 provided on the incident side of the incident light L in the first photoelectric converter 13, and a first light-transmitting layer 12 transmitting a specific wavelength and provided between the first on-chip lens 11 and the first photoelectric converter 13. The phase-difference detection pixel 20 may include a second photoelectric converter 23, a pixel separation wall 40 formed between the second photoelectric converter 23 and the first photoelectric converter 13 adjacent to the second photoelectric converter 23, a boundary separation wall 41 separating the second photoelectric converter 23 into two or more, a second on-chip lens 21 provided on the incident side of the incident light L in the second photoelectric converter 23 and having a greater diameter than the first on-chip lens 11, and a second light-transmitting layer 22 transmitting a specific wavelength and provided between the second on-chip lens 21 and the second photoelectric converter 23. The center of the second photoelectric converter separated into a plurality of parts by the boundary separation wall 41 in the phase-difference detection pixel 20 of the outer peripheral portion of the pixel array 110 may be provided on the outer peripheral side of the pixel array 110 as compared to the center of the pixel separation wall 40.

According to the solid-state image sensor 1 configured as described above, the on-chip lens of the phase-difference detection pixel and the on-chip lens of the pixel adjacent to the phase-difference detection pixel may be configured not to overlap each other, and the sensitivity difference between the pixels adjacent to the phase-difference detection pixel may be reduced.

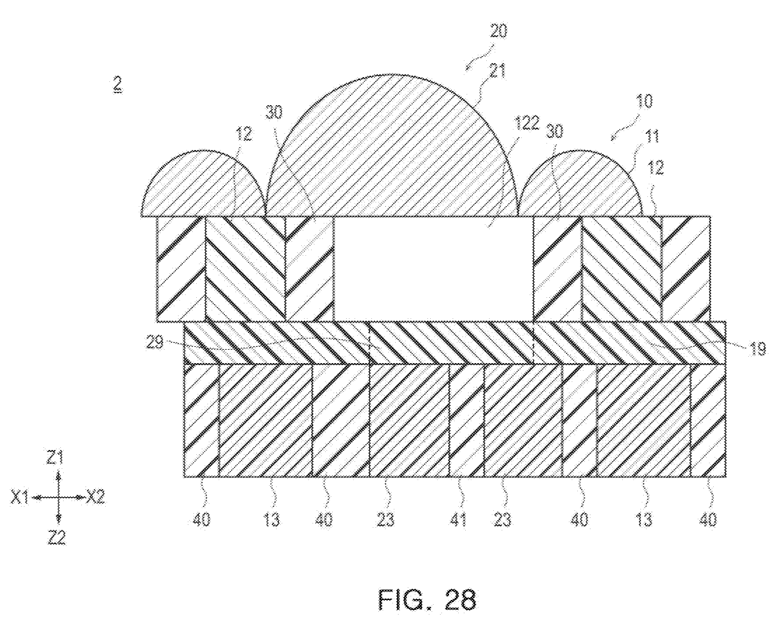

FIG. 28 illustrates a view corresponding to FIG. 27 of the solid-state image sensor 2 according to modified example 1. As illustrated in FIG. 28, the second light-transmitting layer 122 of the solid-state image sensor 2 according to modified example 1 may function as a white filter transmitting light having a specific wavelength that is approximately the entire visible light region.

According to such a configuration, a separation ratio may be improved, and the sensitivity of the phase-difference detection pixel 20 may be improved.

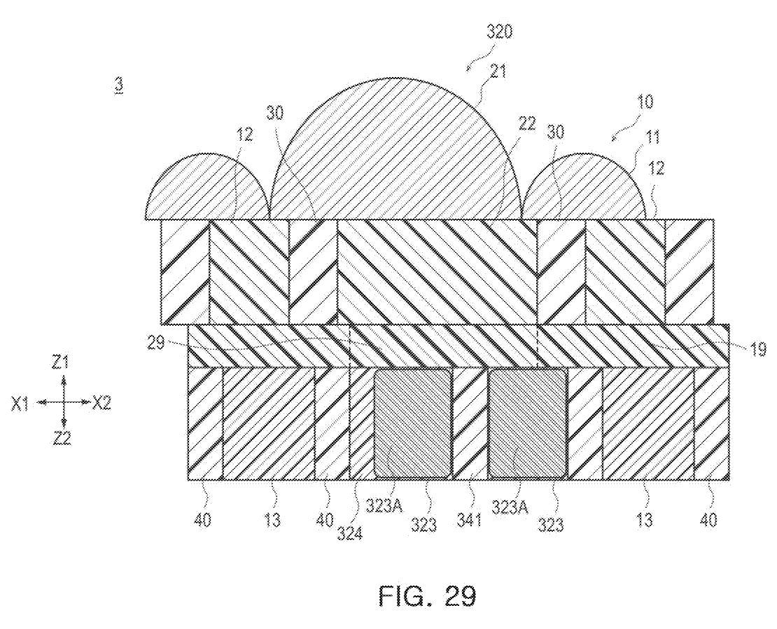

FIG. 29 illustrates a view corresponding to FIG. 27 of a solid-state image sensor 3 according to modified example 2. As illustrated in FIG. 29, a phase-difference detection pixel 320 of the solid-state image sensor 3 according to modified example 2, may be divided so as to have different thicknesses in the X-direction by a boundary separation wall 341. For example, the phase-difference detection pixel 320 may be divided so that a left side of the phase-difference detection pixel 320 is thicker than a right side of the phase-difference detection pixel 320. In this case, a second photoelectric converter 323A may be formed by performing doping with impurities so that a region of the second photoelectric converter 323A becomes symmetrical left and right with respect to the boundary separation wall 341. In this case, a region 324 on the left side of the second photoelectric converter 323A on the left side of the phase-difference detection pixel 320 may be a region that does not function as a photoelectric converter. With such a configuration, the same effect as the solid-state image sensor 1 according to an example embodiment may be achieved.

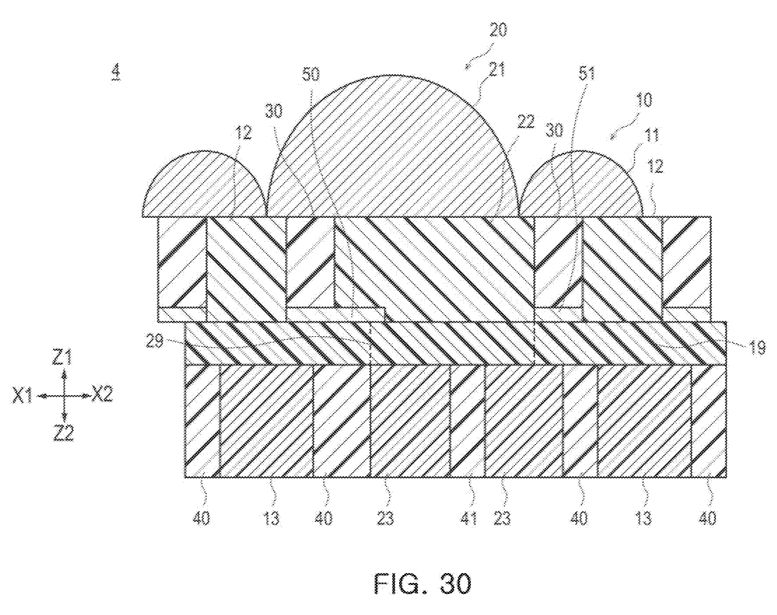

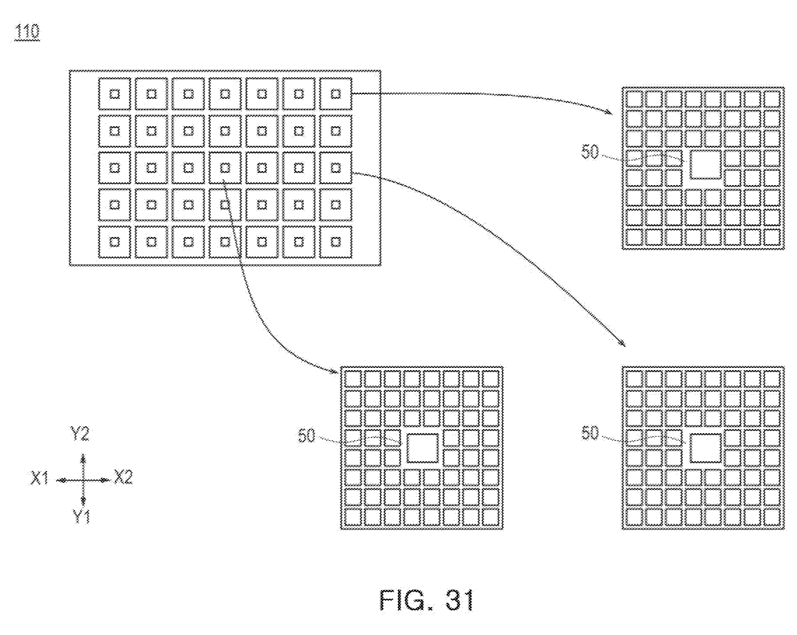

FIG. 30 illustrates a view corresponding to FIG. 27 of a solid-state image sensor 4 according to modified example 3. In the solid-state image sensor 4 according to modified example 3, as illustrated in FIG. 30, metal shielding walls 50 and 51 having asymmetrical thicknesses in the plane direction may be inserted between a pair of light-transmitting layer separation walls 30 provided between the second light-transmitting layer 22 and the first light-transmitting layer 12, and the anti-reflection layers 19 and 29. The metal shielding wall 50 may have a greater thickness in the plane direction than that of the light-transmitting layer separation wall 30, as illustrated in FIG. 30. The metal shielding wall 51 may have a thickness in the plane direction approximately equal to that of the light-transmitting layer separation wall 30, as illustrated in FIG. 30. The metal shielding wall 50 may form an opening when light is incident on the phase-difference detection pixel, as illustrated in FIG. 31, and the opening may be provided on the outer periphery of the pixel array as compared to the center of the pixel separation wall 40, similarly to the center of the second photoelectric converter separated into a plurality of parts by the boundary separation wall 41 described above.

According to such a configuration, the pupil correction amount of the phase-difference detection pixel 20 may be approximately equal to the pupil correction amount of the pixel 10.

The disclosure is not limited to the above-described embodiments and the accompanying drawings but is defined by the appended claims. Therefore, those of ordinary skill in the art may make various replacements, modifications, or changes, and combinations of example embodiments without departing from the scope of the inventive concept of the disclosure defined by the appended claims, and these replacements, modifications, or changes should be construed as being included in the scope of the inventive concept of the disclosure.

What is claimed is:

1. A solid-state image sensor comprising:
a pixel array in which a plurality of pixels configured to generate an electric signal according to incident light are arranged in a two-dimensional shape, the plurality of pixels comprising a plurality of first pixels and a plurality of second pixels,
a first pixel, among the plurality of first pixels, comprises:
a first photodiode;
a first lens provided on the first photodiode; and
a first light-transmitting layer configured to transmit light having a first wavelength in the incident light,
a second pixel, among the plurality of second pixels, comprises:
a second photodiode;
a second lens provided on the second photodiode, the second lens having a greater diameter than the first lens;
a second light-transmitting layer configured to transmit the light having a second wavelength in the incident light; and
an optical path shortening layer provided between the second lens and the second photodiode,
wherein the optical path shortening layer has a refractive index higher than a refractive index of an adjacent film, and
wherein the second pixel is provided in a region of the pixel array requiring pupil correction, and
wherein the second lens, the optical path shortening layer and the second light-transmitting layer of the second pixel have different pupil correction amounts, respectively.

2. The solid-state image sensor of claim 1, wherein a center of the optical path shortening layer in a plane of the incident surface is provided on a straight line connecting a center of the second lens in the plane and a center of the second pixel in the plane.

3. The solid-state image sensor of claim 1, wherein the optical path shortening layer is provided between the second lens and the second light-transmitting layer.

4. The solid-state image sensor of claim 1, wherein the optical path shortening layer is provided between the second light-transmitting layer and the second photodiode.

5. The solid-state image sensor of claim 1, wherein the optical path shortening layer comprises a high refractive index portion and an anti-reflection portion provided on a first surface of the high refractive index portion on which the incident light is incident in the high refractive index portion and a second surface opposite to the first surface of the high refractive index portion.

6. The solid-state image sensor of claim 5, wherein the anti-reflection portion is formed of an anti-reflection film.

7. The solid-state image sensor of claim 5, wherein the anti-reflection portion has an anti-reflection structure having an uneven shape.

8. The solid-state image sensor of claim 1, wherein the incident surface of the optical path shortening layer is inclined so that a thickness of the optical path shortening layer gradually increases toward a direction in which an incident angle increases with respect to a principal ray of the incident light.

9. The solid-state image sensor of claim 1, wherein a cross-sectional shape of the optical path shortening layer is one of a rectangle, a trapezoid or a polygon.

10. The solid-state image sensor of claim 1, wherein a shape of the optical path shortening layer in a plane is one of a square, a rectangle, a trapezoid, a polygon, a circle or an ellipse.

11. The solid-state image sensor of claim 1, wherein the optical path shortening layer is provided only in the second pixel provided, among the first pixel and the second pixel provided in the region requiring the pupil correction.

12. The solid-state image sensor of claim 1, wherein at least one of a width or a thickness of a cross-sectional shape of the optical path shortening layer increases according to an image height from the center of the pixel array in which the plurality of second pixels are provided.

13. A solid-state image sensor comprising:
a pixel array on a chip substrate, the pixel array comprising a first pixel configured to generate an electric signal according to incident light and a second pixel configured to detect a phase-difference,
wherein the first pixel comprises:
a first photodiode;
a first lens provided on the first photodiode;
a first light-transmitting layer provided between the first lens and the first photodiode, the first light-transmitting layer configured to transmit a first wavelength; and
a first separation wall provided between the first light-transmitting layer and a first adjacent first light-transmitting layer adjacent to the first light-transmitting layer, and
wherein the second pixel comprises:
a second photodiode;
a second lens provided on second photodiode, the second lens having a diameter greater than a diameter of the first lens;
a second light-transmitting layer provided between the second lens and the second photodiode, the second light-transmitting layer configured to transmit a second wavelength; and
a second separation wall provided between the second light-transmitting layer and a second adjacent first light-transmitting layer adjacent to the second light-transmitting layer, and
wherein in an outer peripheral portion of the pixel array, a pupil correction amount of the second light-transmitting layer in the second pixel is greater than a pupil correction amount of the second separation wall of the second pixel.

14. The solid-state image sensor of claim 13, wherein the pupil correction amount of the second light-transmitting layer in the second pixel in the outer peripheral portion of the pixel array is greater than a pupil correction amount of the first separation wall of the first pixel adjacent to the second pixel.

15. The solid-state image sensor of claim 13, wherein the second light-transmitting layer of the second pixel is provided to be shifted toward a side projected on a plane of an incident direction of the incident light.

16. The solid-state image sensor of claim 13, wherein a pair of second separation walls provided between the second light-transmitting layer of the second pixel and the first light-transmitting layer of the first pixel have asymmetrical thicknesses in a plane direction.

17. The solid-state image sensor of claim 13, wherein a pair of first light-transmitting layers of the first pixel adjacent to the second pixel have the same thicknesses in a plane direction.

18. A solid-state image sensor comprising:
a pixel array on a chip substrate, the pixel array comprising a first pixel configured to generate an electric signal according to incident light and a second pixel configured to detect a phase-difference,
wherein the first pixel comprises:
a first photodiode;
a first lens provided on the first photodiode; and
a first light-transmitting layer provided between the first lens and the first photodiode, the first light-transmitting layer configured to transmit a first wavelength,
wherein the second pixel comprises:
a second photodiode;
a pixel separation wall formed between the second photodiode and the first photodiode adjacent to the second photodiode;
a boundary separation wall separating the second photodiode into a plurality of portions;
a second lens provided on the second photodiode, the second lens having a diameter greater than a diameter of the first lens; and
a second light-transmitting layer provided between the second lens and the second photodiode, the second light-transmitting layer configured to transmit a second wavelength, and
wherein a center of the second photodiode in the second pixel located in an outer peripheral portion of the pixel array is provided on an outer peripheral side of the pixel array as compared to a center of the pixel separation wall.

19. The solid-state image sensor of claim 18, wherein the boundary separation wall is provided to be shifted to an opposite side from a side projected on a plane of an incident direction of the incident light.

20. The solid-state image sensor of claim 18, wherein a pair of pixel separation walls adjacent to the second photodiode and the first photodiode have asymmetrical thicknesses in a plane direction.
